(19) United States
(12) Patent Application Publication
(10) Pub. No.: US 2025/0341975 A1
(43) Pub. Date: Nov. 6, 2025

(54) MEMORY DEVICE PROVIDING COMPUTE-IN-MEMORY, OPERATION METHOD THEREOF, AND ELECTRONIC DEVICE INCLUDING THE SAME

(71) Applicant: Samsung Electronics Co., Ltd., Suwon-si (KR)

(72) Inventors: Hoi-Jun YOO, Daejeon (KR); Soyeon UM, Daejeon (KR)

(73) Assignees: Samsung Electronics Co., Ltd., Suwon-si (KR); KOREA ADVANCED INSTITUTE OF SCIENCE AND TECHNOLOGY, Daejeon (KR)

(21) Appl. No.: 18/984,160

(22) Filed: Dec. 17, 2024

(30) Foreign Application Priority Data
May 2, 2024 (KR) 10-2024-0058729
Jul. 5, 2024 (KR) 10-2024-0088951

(51) Int. Cl. G06F 3/06; G11C 11/412; G11C 11/418; H03K 19/20

(52) U.S. Cl. CPC G06F 3/0625; G06F 3/064; G06F 3/0673; G11C 11/412; G11C 11/418; H03K 19/20

(57) ABSTRACT

A memory device including a wordline decoder that controls a plurality of wordlines and selects a wordline, to which a first turn-on voltage is applied, depending on a weight value to be applied to an activation value, a first memory cell array that includes memory cells respectively connected to wordlines, and a shift adder that is connected to the first memory cell array through a first bitline and a first bitline bar and generates a first initial calculation result by adding a first input received through the first bitline and a second input received through the first bitline bar. The first memory cell array stores a first activation value including a first bit and a second bit. The first bit is stored in a first memory cell connected to the first wordline. The second bit is stored in a second memory cell connected to the second wordline.

### CROSS-REFERENCE TO RELATED APPLICATIONS

This application claims the benefit of priority under 35 U.S.C. § 119 to Korean Patent Application Nos. 10-2024-0058729 filed on May 2, 2024, and 10-2024-0088951 filed on Jul. 5, 2024, in the Korean Intellectual Property Office, the disclosures of which are incorporated by reference herein in their entireties.

### BACKGROUND

Embodiments of the present disclosure described herein relate to a semiconductor memory device, and more particularly, relate to a memory device providing a compute-in-memory, an operation method thereof, and an electronic device including the same.

Processors which implement or support a deep neural network (DNN) need to perform a large amount of computation. The bandwidth and speed of a memory device are improved to coincide with the computational requirements of the processor. Also, a memory device to which a compute-in-memory is applied to help with the computing speed of the processor is used as a buffer memory in the processor.

To perform the compute-in-memory, there should be provided multiplications between weights and activation values on the deep neural network. To perform the multiplications optimally, there is required a change in a way to store the activation values. Also, to reduce power consumption, there is required a way to apply a memory cell whose structure is different in shape from a structure of a conventional memory cell.

### SUMMARY

Embodiments of the present disclosure provide a memory device providing a compute-in-memory capable of enabling fast execution of multiplication and addition operations between an activation value and a weight, reducing power consumption of an operation method of the memory device, and an electronic device including the memory device.

According to an embodiment, a memory device includes a wordline decoder that controls a plurality of wordlines and selects a wordline, to which a first turn-on voltage is applied, depending on a weight value to be applied to an activation value, a first memory cell array that includes memory cells respectively connected to wordlines including a first wordline and a second wordline from among the plurality of wordlines, and a shift adder that is connected to the first memory cell array through a first bitline and a first bitline bar and generates a first initial calculation result by adding a first input received through the first bitline and a second input received through the first bitline bar. The first memory cell array stores a first activation value including a first bit and a second bit. The first bit is stored in a first memory cell connected to the first wordline and the second wordline. The second bit is stored in a second memory cell connected to the second wordline.

According to an embodiment, an operation method of a memory device which provides a compute-in-memory includes determining signs of a first activation value and a second activation value stored in a memory cell array including a plurality of memory cells connected to a plurality of wordlines, determining a sign of a first weight to be applied to the first activation value and a sign of a second weight to be applied to the second activation value, and adding a first calculation result obtained by applying the first weight to the first activation value and a second calculation result obtained by applying the second weight to the second activation value for each digit. The first activation value is stored in first memory cells respectively connected to wordlines including a first wordline and a second wordline from among the plurality of wordlines. The first weight is applied to the first activation value, based on selecting a wordline, to which a first turn-on voltage is applied, from among the plurality of wordlines.

According to an embodiment, an accelerator includes a processing unit that controls the accelerator and to perform an operation of the accelerator, and a memory cluster module that stores data of the accelerator and to provide a compute-in-memory. The memory cluster module includes a memory block that stores the data including activation values and performs a weight calculation between the activation values, a weight management block that controls the memory block such that weights are applied to the activation values, and a partial-sum accumulation block that sums an initial calculation result generated by the memory block to generate an overall calculation result. The memory block includes a wordline decoder that controls a plurality of wordlines including a first wordline and a second wordline and applies the weights to the activation values, based on selecting a wordline to which a first turn-on voltage is applied, and a memory cell array that is connected to the plurality of wordlines and stores a first activation value including a first bit and a second bit. The first bit is stored in a first memory cell connected to a first wordline, and the second bit is stored in a second memory cell connected to the second wordline.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating an accelerator according to an embodiment of the present disclosure.

FIG. 2 is a block diagram illustrating a compute-in-memory (CIM) unit of FIG. 1, according to an embodiment of the present disclosure.

FIG. 3 is a block diagram illustrating a memory cluster module of FIG. 2, according to an embodiment of the present disclosure.

FIG. 4A is a block diagram illustrating a memory block of FIG. 3, according to an embodiment of the present disclosure.

FIG. 4B is a circuit diagram illustrating a memory cell of FIG. 4A in detail, according to an embodiment of the present disclosure.

FIG. 5 is a diagram illustrating an example of activation values, according to an embodiment of the present disclosure.

FIG. 6 is a diagram illustrating an example in which activation values of FIG. 5 are stored in a memory block of FIG. 3, according to an embodiment of the present disclosure.

FIG. 7 is a block diagram illustrating an example of an adder tree of FIG. 4A, according to an embodiment of the present disclosure.

FIG. 8 is a diagram illustrating a weight calculation process of a memory block of FIG. 3, according to an embodiment of the present disclosure.

FIG. 9A is a block diagram illustrating a memory block of FIG. 3, according to an embodiment of the present disclosure.

FIG. 9B is a circuit diagram illustrating a memory cell of FIG. 9A in detail, according to an embodiment of the present disclosure.

FIG. 10 is a circuit diagram illustrating an example of a memory cell of FIG. 9A in detail, according to an embodiment of the present disclosure.

FIG. 11 is a diagram illustrating a weight calculation process of a memory block of FIG. 3, according to an embodiment of the present disclosure.

FIG. 12 is a block diagram illustrating a shift adder, according to an embodiment of the present disclosure.

FIGS. 13A and 13B are diagrams illustrating a weight calculation process of a memory block of FIG. 3, according to an embodiment of the present disclosure.

FIG. 14 is a flowchart illustrating an operation method of a memory cluster module of FIG. 2, according to an embodiment of the present disclosure.

FIG. 15 is a block diagram illustrating an electronic system according to an embodiment of the present disclosure.

FIG. 16 is a block diagram illustrating an electronic system, according to an embodiment of the present disclosure.

### DETAILED DESCRIPTION

Below, embodiments of the present disclosure will be described in detail and clearly to such an extent that an ordinary one in the art easily carries out the present disclosure.

In the detailed description, components which are described with reference to the terms “unit”, “module”, “block”, “˜er or ˜or”, etc. and function blocks which are illustrated in drawings will be implemented in the form of software or hardware or a combination thereof. For example, the software may include a machine code, firmware, an embedded code, and application software. For example, the hardware may include an electrical circuit, an electronic circuit (e.g., an analog circuit or a digital circuit), a processor, a computer, an integrated circuit, integrated circuit cores, a pressure sensor, an inertial sensor, a microelectromechanical system (MEMS), a passive element, or a combination thereof.

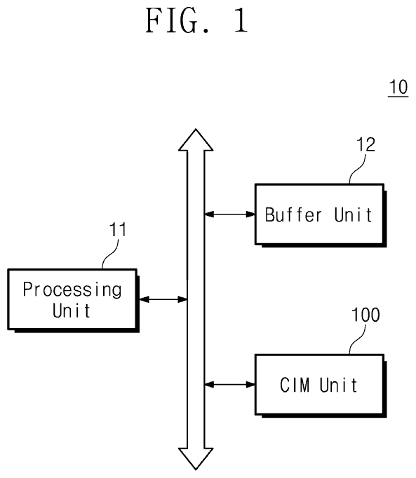

FIG. 1 is a block diagram illustrating an accelerator according to an embodiment of the present disclosure. Referring to FIG. 1, an accelerator 10 may include a processing unit 11, a buffer unit 12, and a compute-in-memory (CIM) unit 100.

The accelerator 10 may implement an artificial intelligence or the like, may perform calculations (or computations) necessary to implement the artificial intelligence or the like, and may provide a result. In an embodiment, the accelerator 10 may implement deep learning such as a deep neural network (DNN), a convolution neural network (CNN), or a transformer, may implement a training operation or an inference operation of machine learning, or may implement artificial intelligence (AI). In an embodiment, the accelerator 10 may perform calculations necessary to implement the artificial intelligence, the machine learning, etc. and may provide a result.

The processing unit 11 may control operations of the accelerator 10. In an embodiment, the processing unit 11 may control the accelerator 10 to perform an operation corresponding to a request which the accelerator 10 receives. In an embodiment, under control of the processing unit 11, a response generated according to the operation of the accelerator 10 may be transferred to an external device (e.g., a central processing unit (CPU) or any other electronic device).

In an embodiment, the processing unit 11 may control any other components of the accelerator 10. For example, the processing unit 11 may control operations of the buffer unit 12 and the CIM unit 100 which are included in the accelerator 10. The processing unit 11 may perform calculations necessary for the operation of the accelerator 10. For example, the processing unit 11 may perform calculations necessary to implement the artificial intelligence or the deep learning. In an embodiment, under control of the processing unit 11, the CIM unit 100 may perform some or all of the calculations necessary for the operation of the accelerator 10. In an embodiment, the processing unit 11 may implement various algorithms necessary for the operation of the accelerator 10 or may perform calculations necessary to implement the algorithms.

The buffer unit 12 may store data necessary for the operation of the accelerator 10. In an embodiment, the buffer unit 12 may store program codes or source codes which the processing unit 11 will execute. For example, the buffer unit 12 may store a source code to be executed by the processing unit 11 and data necessary to execute the source code and may provide the source code and the data to the processing unit 11. In an embodiment, the buffer unit 12 may include a memory device. For example, the buffer unit 12 may include a volatile memory device (e.g., a static random access memory (SRAM) or a dynamic random access memory (DRAM)) or a non-volatile memory device.

The CIM unit 100 may store data necessary for the operation of the accelerator 10. The CIM unit 100 may perform calculations necessary for the operation of the accelerator 10. For example, the CIM unit 100 may store data necessary for the operation of the accelerator 10 and may perform a computation between the stored data. In an embodiment, the CIM unit 100 may perform calculations necessary for the operation of the accelerator 10 implementing the artificial intelligence.

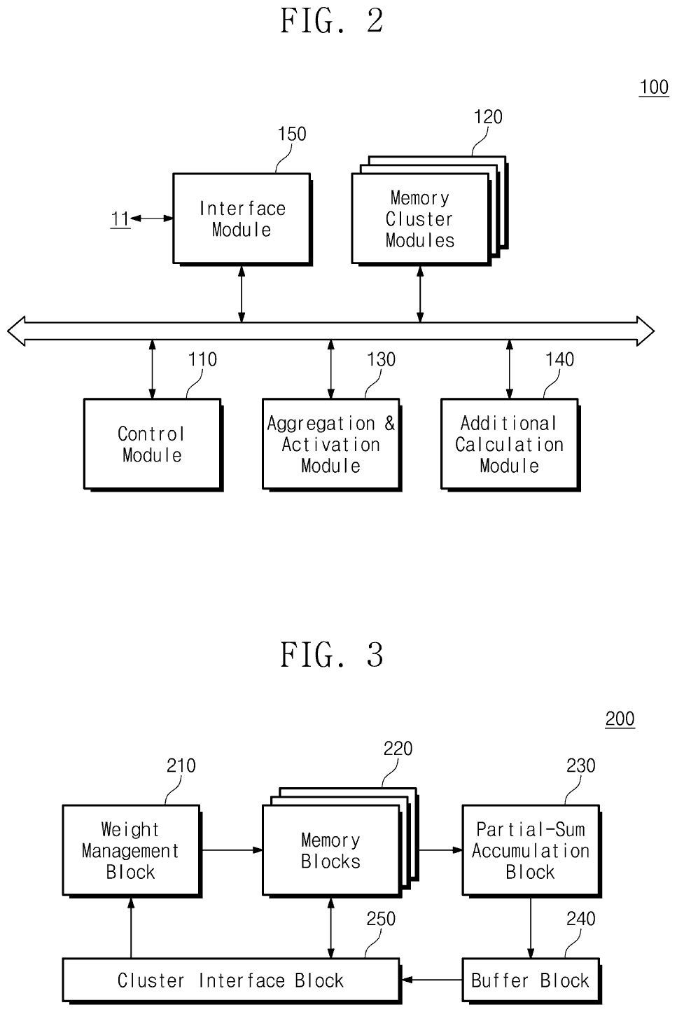

The CIM unit 100 according to an embodiment of the present disclosure may provide a compute-in-memory or an in-memory compute. For example, the CIM unit 100 may include a memory device which provides the compute-in-memory. When the CIM unit 100 writes or reads data or performs a computation between data, the CIM unit 100 may allow a small amount of power to be consumed. In an embodiment, under control of the CIM unit 100, a weight may be applied to data, based on the order of reading bits by which data are stored. The CIM unit 100 according to an embodiment of the present disclosure will be described in detail with reference to FIGS. 2 to 14.

FIG. 2 is a block diagram illustrating a CIM unit according to an embodiment of the present disclosure in detail. Referring to FIG. 2, the compute-in-memory (CIM) unit 100 may include a control module 110, memory cluster modules 120, an aggregation and activation module 130, an additional calculation module 140, and an interface module 150. The CIM unit 100 according to an embodiment of the present disclosure will be described in detail with reference to FIGS. 1 and 2.

The control module 110 may control operations of the CIM unit 100. In an embodiment, the control module 110 may control the operations of the CIM unit 100 so as to respond to the control of the processing unit 11 of FIG. 1. In an embodiment, the control module 110 may control each component of the CIM unit 100. For example, depending on a data read or write request of the processing unit 11, the control module 110 may control the memory cluster modules 120 or the interface module 150 such that data are written in or read from the memory cluster modules 120. For another example, the control module 110 may control the memory cluster modules 120, the aggregation and activation module 130, or the additional calculation module 140 depending on a computation request of the processing unit 11 such that data are computed in the memory cluster modules 120.

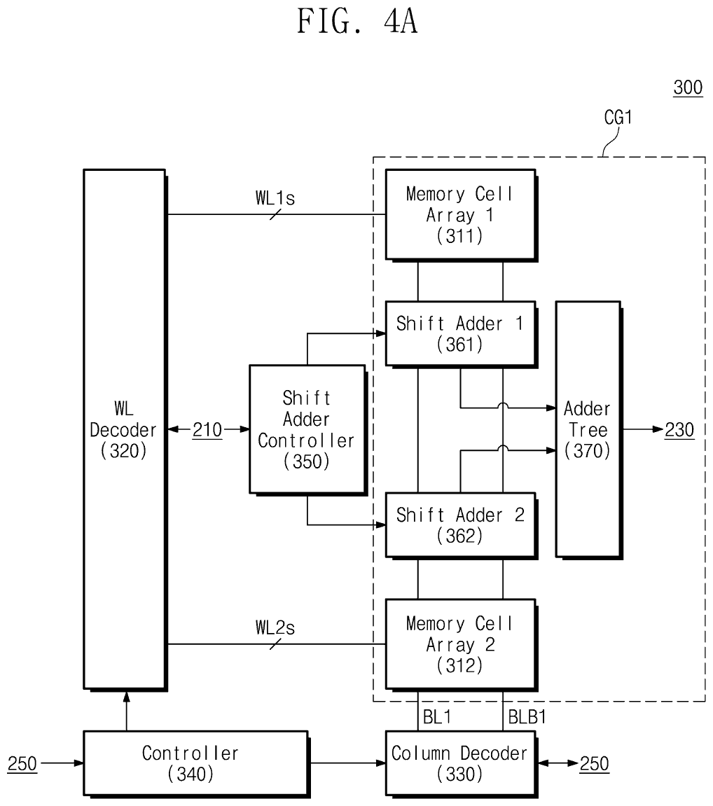

The memory cluster modules 120 may store data of the CIM unit 100. In an embodiment, the memory cluster modules 120 may perform the compute-in-memory. Under control of the control module 110, the memory cluster modules 120 may write or read data or may perform the computation between the stored data. The memory cluster modules 120 will be described in detail with reference to FIG. 3.

The aggregation and activation module 130 may manage calculations of the memory cluster modules 120. In an embodiment, under control of the aggregation and activation module 130, two or more memory cluster modules 120 may cooperate with each other to perform calculations. For example, under control of the control module 110 or depending on the amount of computation of the CIM unit 100 or a magnitude of a computation which the CIM unit 100 performs, the aggregation and activation module 130 may manage or control the number of memory cluster modules 120 to be controlled or may manage or control calculations which each of the memory cluster modules 120 will perform. In an embodiment, the aggregation and activation module 130 may generate data to be provided to the processing unit 11, based on computational result of the memory cluster modules 120.

The additional calculation module 140 may perform additional calculations necessary for the operation of the CIM unit 100. In an embodiment, the additional calculation module 140 may perform calculations which the memory cluster modules 120 do not support. For example, the additional calculation module 140 may receive a weight calculation result of the memory cluster modules 120 and may perform additional calculations necessary for the operation of the CIM unit 100. For example, the additional calculations may include a vector calculation, a matrix calculation, a filtering operation, etc.

The interface module 150 may support communication between the outside and the CIM unit 100. In an embodiment, the interface module 150 may receive a request from the processing unit 11 or may transmit a response to the request to the processing unit 11. For example, depending on the data read request from the CIM unit 100, the interface module 150 may allow data to be transferred to the processing unit 11. The interface module 150 may transfer a request of the processing unit 11 to the control module 110 such that the CIM unit 100 operates depending on the request.

FIG. 3 is a block diagram illustrating a memory cluster module of FIG. 2, according to an embodiment of the present disclosure. A memory cluster module 200 may be one of the memory cluster modules 120 of FIG. 2. Referring to FIG. 3, the memory cluster module 200 may include a weight management block 210, memory blocks 220, a partial-sum accumulation block 230, a buffer block 240, and a cluster interface block 250. A memory cluster module according to an embodiment of the present disclosure will be described with reference to FIGS. 2 and 3.

The weight management block 210 may manage a weight necessary for the calculation of the CIM unit 100. In the calculation of the CIM unit 100, weights may be applied to the calculation under control of the weight management block 210. In an embodiment, the weight management block 210 may store weights to be calculated. For example, the weight management block 210 may include a buffer memory which stores weights.

In an embodiment, the weight management block 210 may control the memory blocks 220 such that the calculation of weights is performed. For example, under control of the weight management block 210, weights may be calculated based on controlling the memory blocks 220 such that memory cells targeted for the read operation are selected. Alternatively, under control of the weight management block 210, weights may be applied to data, based on controlling the memory blocks 220 such that memory cells targeted for the read operation are selected. In an embodiment, the weight management block 210 may manage weights, based on the control of the control module 110 of the CIM unit 100 or the aggregation and activation module 130 of the CIM unit 100. For example, the weight management block 210 may receive the control of the control module 110 or the aggregation and activation module 130 through the cluster interface block 250 and may allow a weight to be applied to a calculation in response to the control.

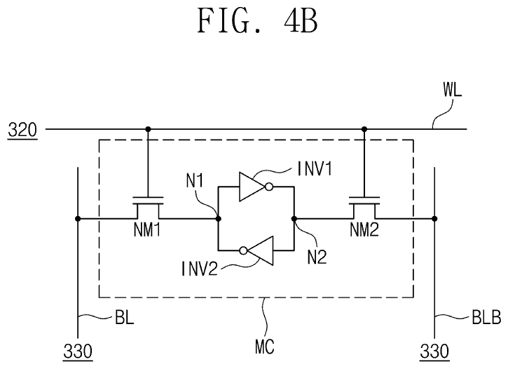

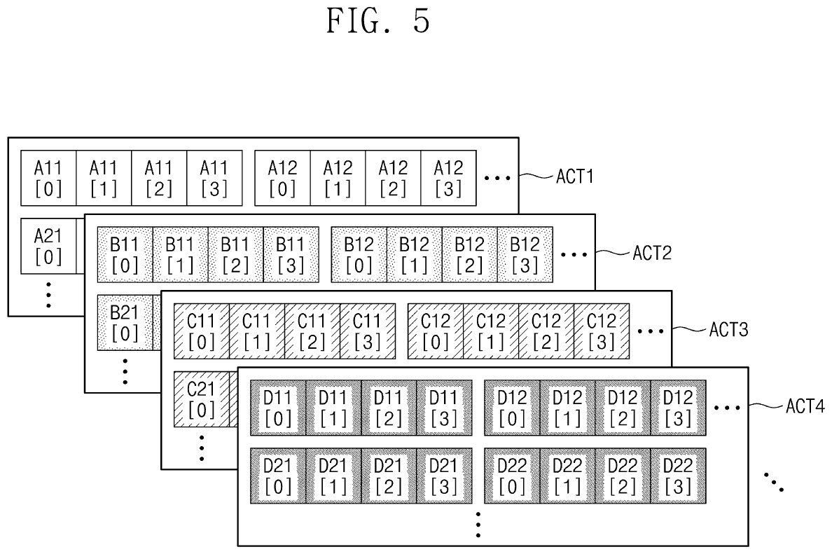

In an embodiment, magnitudes of weights which the weight management block 210 manages may be expressed in the form of a log. For example, the weight management block 210 may manage weights in the form where values of a weight include only exponent values of the power of 2. In detail, for example, when a magnitude of a stored weight is 4, the weight management block 210 may manage and store by using “2” being a value of the logarithm of 2 of the magnitude of the weight (a weight whose magnitude is 4 being expressed by “010” when the weight is expressed in an unsigned 3-bit form). The calculation where the weight management block 210 applies a weight will be described in detail with reference to FIGS. 4A to 10. In an embodiment, weights may be expressed in a sign-size form. For example, the most significant bit (MSB) of each of the weights may indicate a sign of each of the weights.

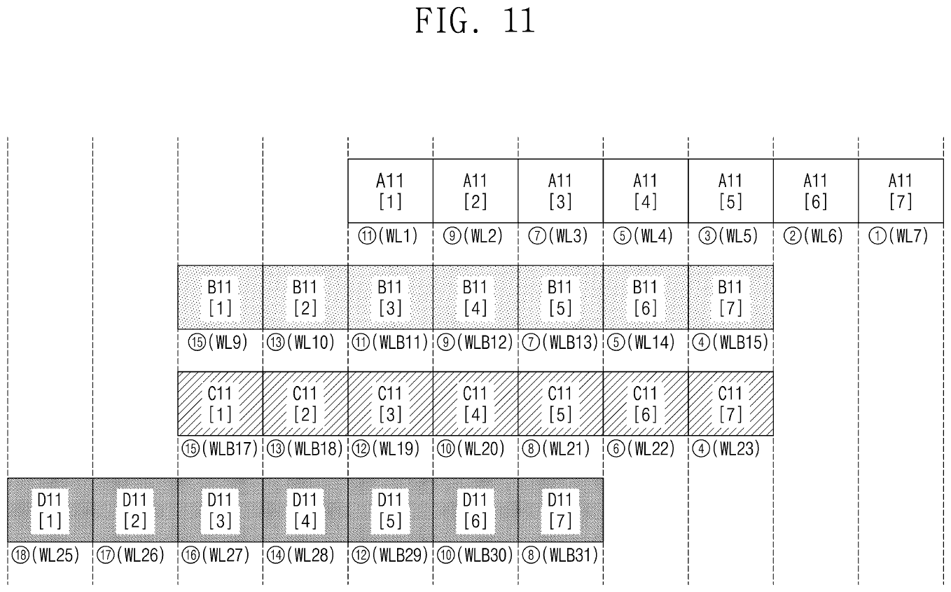

The memory blocks 220 may store data to which the calculation of the CIM unit 100 is applied. For example, the memory blocks 220 may store activation values being the data to which the calculation of the CIM unit 100 is applied. In an embodiment, the memory blocks 220 may perform multiplication calculations between activation values and weights. In an embodiment, the memory blocks 220 may perform addition calculations. For example, the memory blocks 220 may perform multiplications between activation values and weights to generate first calculation result values and may add the first calculation result values to generate second calculation result values. In an embodiment, the memory blocks 220 may perform the matrix calculation or the like, in addition to the weight calculation, based on a data storage structure or the like. A structure and an operation of the memory blocks 220 will be described in detail with reference to FIGS. 4A and 10.

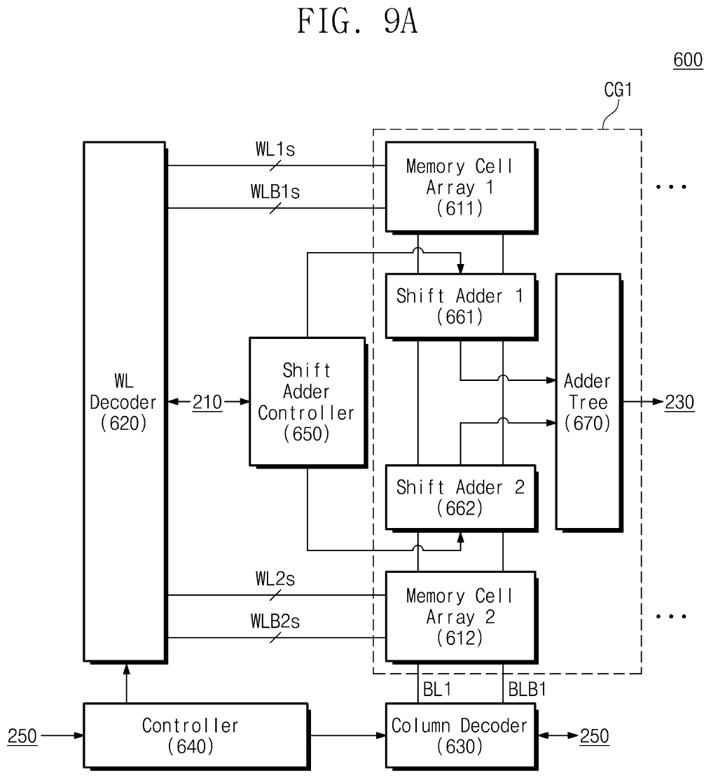

The partial-sum accumulation block 230 may accumulate calculation results (e.g., initial calculation results or intermediate calculation results of FIG. 8, 11, 13A, or 13B) received from the memory blocks 220. The partial-sum accumulation block 230 may generate one or more overall calculation results, based on the calculation results received from the memory blocks 220. In an embodiment, the partial-sum accumulation block 230 may generate the overall calculation results respectively based on the calculation results received from the memory blocks 220. In an embodiment, the partial-sum accumulation block 230 may receive calculation results from two or more memory blocks 220 and may generate an overall calculation result based on the calculation results. For example, the partial-sum accumulation block 230 may generate an overall calculation result, based on calculation results received from some or all of the memory blocks 220.

In an embodiment, the partial-sum accumulation block 230 may adjust a digit of calculation results received from the memory blocks 220. In an embodiment, the partial-sum accumulation block 230 may add the calculation results to coincide with the digit. For example, the partial-sum accumulation block 230 may generate an overall calculation result by arranging and adding calculation results of one or more memory blocks 220 to coincide with the digit while receiving the calculation results from the memory blocks 220. For another example, the partial-sum accumulation block 230 may generate an overall calculation result by receiving calculation results from one or more memory blocks 220 and adding all the received calculation results to coincide with the digit.

The buffer block 240 may receive one or more overall calculation results from the partial-sum accumulation block 230 and may temporarily store the one or more overall calculation results. The buffer block 240 may store the overall calculation result thus received and may then transfer the overall calculation result to the cluster interface block 250. The memory cluster module 200 of FIG. 3 is described as including the buffer block 240, but the present disclosure is not limited thereto. In an embodiment, the memory cluster module 200 may not include the buffer block 240, and the partial-sum accumulation block 230 may directly transfer the overall calculation result to the cluster interface block 250.

The communication between the memory cluster module 200 and any other components of the CIM unit 100 may be performed under control of the cluster interface block 250. In an embodiment, the cluster interface block 250 may receive data to be written in the memory blocks 220 from any other components of the CIM unit 100. In an embodiment, the cluster interface block 250 may receive the control of the calculation of the memory blocks 220 so as to be transferred to any other blocks. For example, under control of the cluster interface block 250, the overall calculation result received from the buffer block 240 may be transferred to the aggregation and activation module 130 or the additional calculation module 140 of FIG. 2.

In an embodiment, under control of the cluster interface block 250, data may be written in or read from the memory blocks 220. For example, the cluster interface block 250 may transfer data to be written in the memory blocks 220 and a write command to the memory blocks 220. For example, the cluster interface block 250 may transfer a read command for data stored in the memory blocks 220 to the memory blocks 220 and may transfer the read data to the control module 110 or the interface module 150 of FIG. 2. In an embodiment, the cluster interface block 250 may transfer the data write or read command to the memory blocks 220 under control of the control module 110.

FIG. 4A is a block diagram illustrating a memory block according to an embodiment of the present disclosure. FIG. 4B is a circuit diagram illustrating one memory cell included in memory cell arrays of FIG. 4A. A memory block 300 of FIG. 4A may be one of the memory blocks 220 of FIG. 3.

Referring to FIG. 4A, the memory block 300 may include memory cell arrays 311 and 312, a wordline decoder 320, a column decoder 330, a controller 340, a shift adder controller 350, shift adders 361 and 362, and an adder tree 370. The memory cell arrays 311 and 312 may store data. In an embodiment, the memory cell arrays 311 and 312 may include a plurality of memory cells. The memory cell arrays 311 and 312 may be connected to a plurality of wordlines and may be connected to a bitline and a bitline bar. For example, the first memory cell array 311 may be connected to first wordlines WL1s and may be connected to a first bitline BL1 and a first bitline bar BLB1.

A structure of one memory cell MC included in the memory cell arrays 311 and 312 will be described with reference to FIG. 4B. Referring to FIG. 4B, the memory cell MC may include a first inverter INV1, a second inverter INV2, a first n-type metal-oxide-semiconductor (NMOS) transistor NM1, and a second NMOS transistor NM2.

The first inverter INV1 may include an input terminal connected to a first node N1 and an output terminal connected to a second node N2. A logic level of the first node N1 and a logic level of the second node N2 may be opposite to each other. For example, when the first node N1 has a logic high level, the logic level of the second node N2 may have a logic low level. The second inverter INV2 may include an input terminal connected to the second node N2 and an output terminal connected to the first node N1.

The first NMOS transistor NM1 may be connected between the first node N1 and a bitline BL and may include a gate node connected to a wordline WL. The second NMOS transistor NM2 may be connected between the second node N2 and a bitline bar BLB and may include a gate node connected to the wordline WL. When a turn-on voltage of the first NMOS transistor NM1 and the second NMOS transistor NM2 is applied to the wordline WL, voltage levels of the first node N1 and the bitline BL may be equalized, and voltage levels of the second node N2 and the bitline bar BLB may be equalized. The memory cell MC described with reference to FIG. 4B may be the same as a static random access memory (SRAM) cell. Below, the description will be given based on a dual inverter structure, but the present disclosure is not limited thereto. For example, an embodiment of a memory cell with an arbitrary cell structure may also be understood as belonging to the scope of the present disclosure.

Returning to FIG. 4A, the wordline decoder 320 may select a wordline to which the turn-on voltage is to be applied. In an embodiment, the wordline decoder 320 may operate under control of the controller 340. For example, under control of the controller 340, the wordline decoder 320 may apply the turn-on voltage to a wordline of memory cells targeted for the read operation or the write operation.

In an embodiment, the wordline decoder 320 may operate under control of the weight management block 210 of FIG. 2. For example, the wordline decoder 320 may apply the turn-on voltage to a word line depending on a weight of the weight management block 210. The wordline decoder 320 may allow a weight to be applied to data of the memory cell arrays 311 and 312, based on the control of the weight management block 210. For example, the wordline decoder 320 may select a wordline to which the turn-on voltage is to be applied, such that data are capable of being read in the order coinciding with a weight calculation of each of data stored in the memory cell arrays 311 and 312. The calculation operation of the wordline decoder 320 will be described in detail with reference to FIG. 8.

The column decoder 330 may be connected to the bitline BL and the bitline bar BLB of the memory cell arrays 311 and 312. The column decoder 330 may provide data to be written in a memory cell of the memory cell arrays 311 and 312 or may receive data read from a memory cell of the memory cell arrays 311 and 312. In an embodiment, the column decoder 330 may operate under control of the controller 340. In an embodiment, the column decoder 330 may receive data to be written through the cluster interface block 250 of FIG. 2 or may transfer read data to the cluster interface block 250 of FIG. 2. For example, under control of the controller 340, the column decoder 330 may transfer data to be written in memory cells of the memory cell arrays 311 and 312 to the memory cells through the bitline BL and the bitline bar BLB.

The controller 340 may control a data write operation or a data read operation of the memory cell arrays 311 and 312. In an embodiment, the controller 340 may control the memory cell arrays 311 and 312, based on controlling the wordline decoder 320 and the column decoder 330. In an embodiment, the controller 340 may control the wordline decoder 320 or the column decoder 330, in response to a command/address received from the cluster interface block 250 of FIG. 3.

The shift adder controller 350 may control the shift adders 361 and 362. In an embodiment, the shift adder controller 350 may operate under control of the weight management block 210 of FIG. 3. For example, the shift adder controller 350 may control the shift adders 361 and 362, based on a control signal received from the weight management block 210.

In an embodiment, the shift adder controller 350 may provide the shift adder 361 with sign information of a calculation result of the shift adder 361 and may provide the shift adder 362 with sign information of a calculation result of the shift adder 362. The shift adder controller 350 may determine signs to be provided to the shift adders 361 and 362, based on sign information provided from the weight management block 210. In an embodiment, the most significant bit (MSB) of each of a weight and data may express a sign. The weight management block 210 may transfer the sign information to the shift adder controller 350, based on MSBs of a weight and data to be input to each of the shift adders 361 and 362, and the shift adder controller 350 may provide sign information corresponding to each of the shift adders 361 and 362, based on the received sign information.

The shift adders 361 and 362 may be connected to the first bitline BL1 and the first bitline bar BLB1 and may perform addition of data. In an embodiment, the shift adders 361 and 362 may sum two bits which are sequentially read. In an embodiment, when the number of bits corresponding to a digit is only “1”, the shift adders 361 and 362 may add the corresponding bit and “0”. For example, when the number of bits corresponding to a digit is only one, the shift adders 361 and 362 may generate a result of adding the corresponding bit and “0” and a sign, under control of the shift adder controller 350.

In an embodiment, the shift adders 361 and 362 may express a negative output signal in a 2's complement form. For example, the shift adders 361 and 362 may generate a 3-bit calculation result, based on sign information and a result of summing two bits sequentially received from the first bitline BL1 and may indicate that an output signal is negative, in a 2's complement form. For example, when a multiplication of a weight and data which the first shift adder 361 computes is positive and all the sequentially received bits are logic “1”, the first shift adder 361 may output a logical value of “010”. For another example, when a multiplication of a weight and data which the first shift adder 361 computes is negative and the sequentially received bits are logic “1” and logic “0”, the first shift adder 361 may output a logical value of “111”.

The calculation results of the shift adders 361 and 362 may be transferred to the adder tree 370. In an embodiment, the shift adders 361 and 362 may be respectively allocated to the memory cell arrays 311 and 312. For example, the first shift adder 361 may be allocated to the first memory cell array 311, and the second shift adder 362 may be allocated to the second memory cell array 312. That is, the first shift adder 361 may add bits read from the first memory cell array 311, and the second shift adder 362 may add bits read from the second memory cell array 312.

The adder tree 370 may generate an intermediate calculation result by adding calculation results received from the shift adders 361 and 362. In an embodiment, the adder tree 370 may transfer the generated intermediate calculation result to the partial-sum accumulation block 230 of FIG. 3. For example, the adder tree 370 may generate an intermediate calculation result by adding a first calculation result received from the first shift adder 361 and a second calculation result received from the second shift adder 362 and may transfer the intermediate calculation result to the partial-sum accumulation block 230 of FIG. 3.

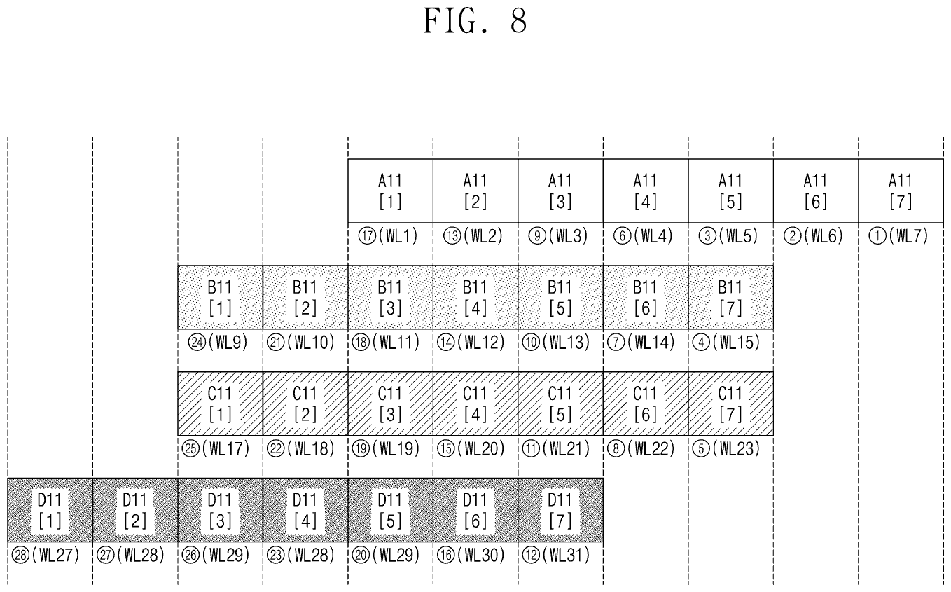

The adder tree 370 may be allocated for each cell group. The adder tree 370 may generate an intermediate calculation result by adding all calculation results received from shift adders included in a cell group. For example, when a first cell group CG1 includes 16 memory cell arrays and 16 shift adders respectively corresponding to the 16 memory cell arrays, the adder tree 370 may sum all of 16 initial calculation results received from the 16 shift adders so as to be transferred to the partial-sum accumulation block 230. The adder tree 370 will be described in detail with reference to FIG. 7.

Referring to FIG. 3, the partial-sum accumulation block 230 may arrange a calculation result received from the adder tree 370 so as to coincide with a digit. In an embodiment, the partial-sum accumulation block 230 may arrange and add calculation results received from the adder tree 370 so as to coincide with a digit. For example, when the partial-sum accumulation block 230 receives a first calculation result and a second calculation result of a digit immediately above the first calculation result from the adder tree 370, the partial-sum accumulation block 230 may perform an accumulation calculation by adding the first calculation result and a doubled value of the second calculation result. The operation of the partial-sum accumulation block 230 will be described in detail with reference to FIG. 8.

The memory block 300 described with reference to FIG. 4A is provided as an example, and the scope of the present disclosure should not be construed as being limited thereto. The first cell group CG1 may additionally include memory cell arrays and shift adders corresponding to the memory cell arrays, and wordlines connected to each of the memory cell arrays may be additionally connected to the wordline decoder 320. Alternatively, the memory block 300 may further include additional cell groups being the same as the first cell group CG1, and each of the additional cell groups may include memory cell arrays, shift adders corresponding to the memory cell arrays, and an adder tree. For example, the memory block 300 may include 32 cell groups, each of the 32 cell groups may include 16 memory cell arrays, 16 shift adders corresponding to the 16 memory cell arrays, and an adder tree, and each of the 16 memory cell arrays may include 32 memory cells respectively connected to 32 wordlines.

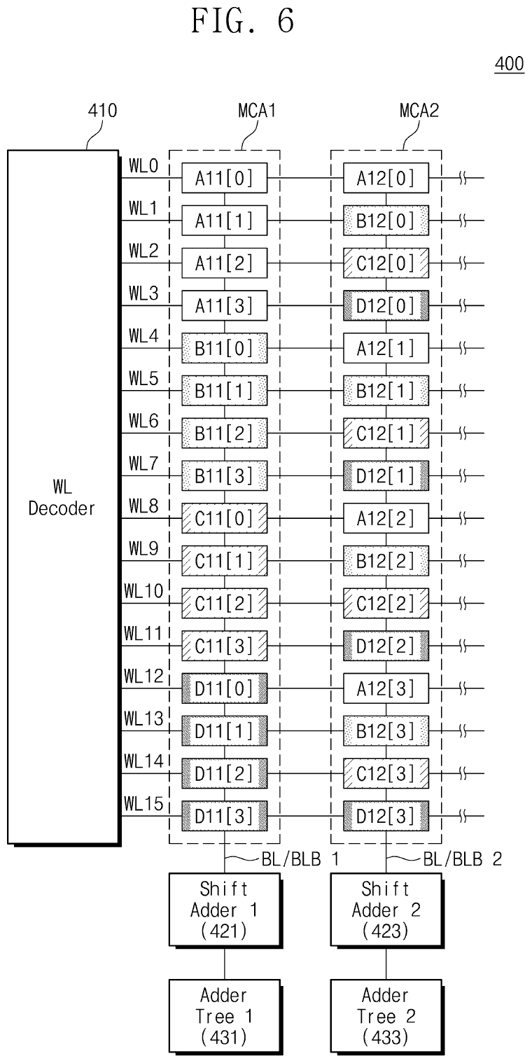

FIG. 5 is a diagram illustrating an example of activation values which the accelerator 10 of FIG. 1 computes, according to an embodiment of the present disclosure. Activation values may be data stored in the CIM unit 100 of FIG. 1 or may be included in the data. Referring to FIG. 5, the accelerator 10 of FIG. 1 may include activation values of 4 channels. For example, the accelerator 10 may include first channel activation values ACT1, second channel activation values ACT2, third channel activation values ACT3, and fourth channel activation values ACT4.

Each of the channel activation values ACT1, ACT2, ACT3, and ACT4 may include a plurality of activation values. For example, the first channel activation values ACTI may include an A11-th activation value A11, and an A12-th activation value A12, an A21-th activation value A21. In an embodiment, each activation value may be expressed by a binary number. For example, referring to FIG. 5, each activation value may be expressed in a 4-bit form, and the MSB of each activation value may indicate a sign. For example, the 0-th bit A11[0] of the A11-th activation value A11 may indicate sign, and the first to third bits A11[1], A11[2], and A11[3] of the A11-th activation value A11 may indicate a magnitude of the A11-th activation value A11.

The number of channels of activation values described with reference to FIG. 5 is provided as an example, and the present disclosure is not limited thereto. The number of bits of each activation value and a sign expression method illustrated in FIG. 5 are provided as an example, and the present disclosure is not limited thereto. For example, each activation value may be expressed by using 8 bits. Below, for convenience of description, differing shading/hatching are utilized depending on channels of activation values. The activation values ACT2 of the second channel are shaded by gray, the activation values ACT3 of the third channel are shaded by a diagonal line, and the activation values ACT4 of the fourth channel are shaded by black.

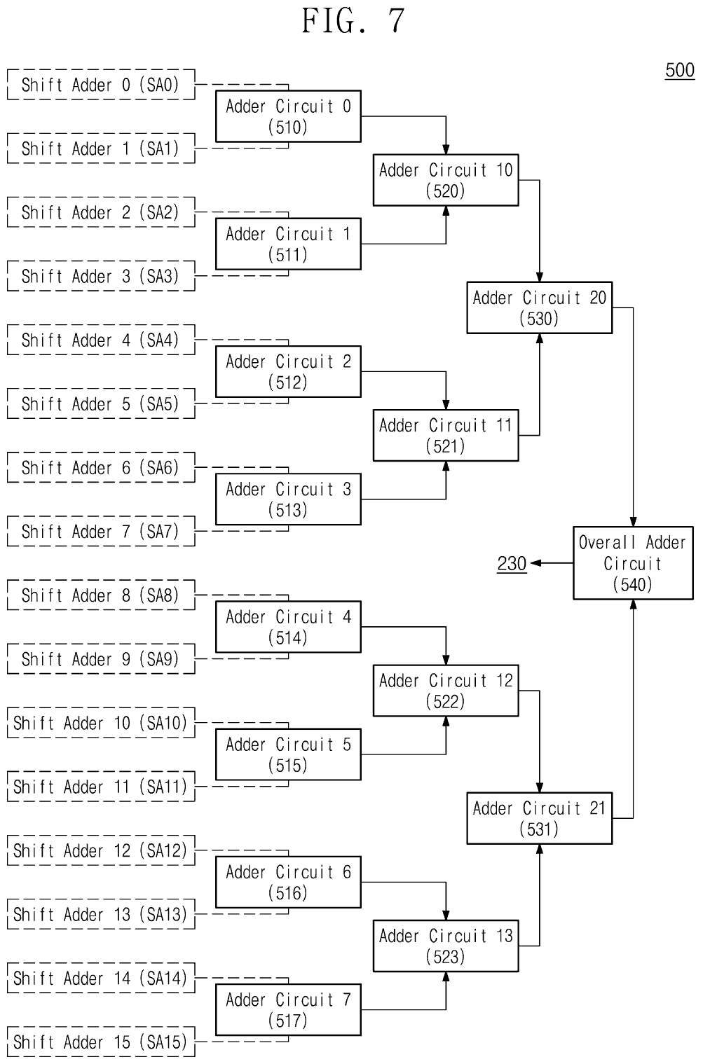

FIG. 6 is a diagram illustrating an example in which data are mapped to a memory cell array of FIG. 4A, according to an embodiment of the present disclosure. Referring to FIG. 6, a memory block 400 may include a first memory cell array MCA1, a second memory cell array MCA2, a wordline decoder 410, a first shift adder 421, a second shift adder 423, a first adder tree 431, and a second adder tree 433. The memory block 400 of FIG. 6 may be a part of the memory block 300 described with reference to FIG. 4A.

Each of the first memory cell array MCA1 and the second memory cell array MCA2 may include a plurality of memory cells. The first memory cell array MCA1 and the second memory cell array MCA2 may be connected to the same word lines. Referring to FIG. 6, the first memory cell array MCA1 may be connected to 16 wordlines, and likewise, the second memory cell array MCA2 may be connected to the same 16 wordlines. The first memory cell array MCA1 may be connected to the first bitline BL1 and the first bitline bar BLB1 and may be connected to the first shift adder 421 through the first bitline BL1 and the first bitline bar BLB1. Likewise, the second memory cell array MCA2 may be connected to a second bitline BL2 and a second bitline bar BLB2 and may be connected to the second shift adder 423 through the second bitline BL2 and the second bitline bar BLB2.

The wordline decoder 410 may be identical or similar to the wordline decoder 320 of FIG. 3A and may select a wordline, to which the turn-on voltage is to be applied, from among wordlines WL0 to WL15. The first shift adder 421 and the second shift adder 423 may be identical or similar to the shift adders 361 and 362 described with reference to FIG. 4A. The first shift adder 421 may add bits received from the first bitline BL1 or the first bitline bar BLB1, and likewise, the second shift adder 423 may add bits received from the second bitline BL2 or the second bitline bar BLB2. The first adder tree 431 and the second adder tree 433 may be identical or similar to the adder tree 370 of FIG. 4A, and the first adder tree 431 may generate a first intermediate calculation result by summing an initial calculation result received from the first shift adder 421 and initial calculation results respectively received from shift adders connected to the first bitline BL1 and the first bitline bar BLB1. Likewise, the second adder tree 433 may generate a second intermediate calculation result by summing an initial calculation result received from the second shift adder 423 and initial calculation results respectively received from shift adders connected to the second bitline BL2 and the second bitline bar BLB2.

Referring to FIG. 5, each activation value may be stored in memory cells connected to the same bitlines. Bits included in each activation value may be stored in memory cells connected to different wordlines. In an embodiment, activation values may be sequentially stored in one memory cell array for each channel. For example, in the first memory cell array MCA1, a A11-th activation value A11, a B11-th activation value B11, a C11-th activation value C11, and a D11-th activation value D11 may be sequentially stored in memory cells connected to the 0-th wordline WL0 to the fifteenth wordline WL15.

In detail, the A11-th activation value A11 may be stored in memory cells respectively connected to the 0-th wordline WL0, the first wordline WL1, the second wordline WL2, and the third wordline WL3. For example, in the A11-th activation value A11, the first bit A11[1] may be stored in a memory cell connected to the first wordline WL1, the first bitline BL1, and the first bitline bar BLB1, and the second bit A11[2] may be stored in a memory cell connected to the second wordline WL2, the first bitline BL1, and the first bitline bar BLB1. Likewise, the B11-th activation value B11 may be stored in memory cells respectively connected to the fourth wordline WL4, the fifth wordline WL5, the sixth wordline WL6, and the seventh wordline WL7. For example, in the B11-th activation value B11, the first bit B11[0] may be stored in a memory cell connected to the fourth wordline WL4, the first bitline BL1, and the first bitline bar BLB1, and the third bit B11[3] may be stored in a memory cell connected to the seventh wordline WL7, the first bitline BL1, and the first bitline bar BLB1. As in the above description, the C11-th activation value C11 may be stored in memory cells which are respectively connected to the eighth to eleventh wordlines WL8, WL9, WL10, and WL11 and are connected to the first bitline BL1 and the first bitline bar BLB1. As in the above description, the D11-th activation value D11 may be stored in memory cells which are respectively connected to the twelfth to fifteenth wordlines WL12, WL13, WL14, and WL15 and are connected to the first bitline BL1 and the first bitline bar BLB1.

In an embodiment, activation values may be sequentially stored depending on a digit and a channel of activation values. For example, in activation values, most significant bits of respective channels may be sequentially stored, and then, second most significant bits of the respective channels may be sequentially stored in memory cells respectively connected to wordlines. For example, in the second memory cell array MCA2, the A12-th activation value A12, the B12-th activation value B12, the C12-th activation value C12, and the D12-th activation value D12 may be stored in memory cells connected to the 0-th wordline WL0 to the fifteenth wordline WL15.

In detail, memory cells connected to the 0-th to third wordlines WL0 to WL3 and connected to the second bitline BL2 and the second bitline bar BLB2 may store 0-th bits of activation values. For example, the 0-th bit A12[0] of the A12-th activation value A12 may be stored in a memory cell connected to the 0-th wordline WL0, the second bitline BL2, and the second bitline bar BLB2; the 0-th bit B12[0] of the B12-th activation value B12 may be stored in a memory cell connected to the first wordline WL1, the second bitline BL2, and the second bitline bar BLB2; the 0-th bit C12[0] of the C12-th activation value C12 may be stored in a memory cell connected to the second wordline WL2, the second bitline BL2, and the second bitline bar BLB2; and, the 0-th bit D12[0] of the D12-th activation value D12 may be stored in a memory cell connected to the third wordline WL3, the second bitline BL2, and the second bitline bar BLB2. In the same method, the first bits of the activation values may be respectively connected to memory cells connected to the fourth to seventh wordlines WLA to WL7; the second bits of the activation values may be respectively connected to memory cells connected to the eighth to eleventh wordlines WL8 to WL11; and, the third bits of the activation values may be respectively connected to memory cells connected to the twelfth to fifteenth wordlines WL12 to WL15.

The data storage manner described with reference to FIG. 6 is provided as an example, and the present disclosure is not limited thereto. In an embodiment, activation values of memory cell arrays sharing the same wordlines may be stored in the same manner. For example, the first memory cell array MCA1 and the second memory cell array MCA2 may store data in the same method as described based on the first memory cell array MCA1. An embodiment in which each of the memory cell arrays MCA1 and MCA2 of FIG. 6 further includes memory cells should also be construed as belonging to the scope of the present disclosure.

Also, the activation value storage manner described with reference to FIG. 6 is provided as an example; in addition to the above examples, it should be construed as any activation value storage manner belongs to the scope of the present disclosure as long as bits of each activation value are stored in memory cells connected to different wordlines. For example, in a memory cell array, activation values of channels may be sequentially stored in memory cells respectively connected to wordlines, and each activation value may be stored such that the least significant bit is stored in a memory cell connected to the uppermost wordline and the most significant bit is stored in a memory cell connected to the lowermost wordline. For example, assuming that the A13-th activation value A13 is stored in memory cells respectively connected to the 0-th to third wordlines WL0 to WL3 in the first memory cell array MCA1, the 0-th bit A13[0] of the A13-th activation value A13 may be stored in the memory cell connected to the third wordline WL3, and the third bit A13[3] of the A13-th activation value A13 may be stored in the memory cell connected to the 0-th wordline WL0. Below, the description will be given based on a method of storing activation values in the method described through the first memory cell array MCA1. However, this is provided as an example, and the scope of the present disclosure should not be construed as being limited thereto.

FIG. 7 is a block diagram illustrating an example of an adder tree of FIG. 4A, according to an embodiment of the present disclosure. An adder tree 500 of FIG. 7 will be described based on the condition that a cell group including an adder tree includes 16 memory cell arrays and 16 shift adders. However, this is provided as an example, and the scope of the present disclosure is not limited thereto. Referring to FIG. 7, the adder tree 500 may include 0-th to seventh adder circuits 510 to 517, tenth to thirteenth adder circuits 520 to 523, a twentieth adder circuit 530, a twenty-first adder circuit 531, and an overall adder circuit 540.

The 0-th to seventh adder circuits 510 to 517 may be adder circuits of a first layer. Each of the 0-th to seventh adder circuits 510 to 517 may be connected to two shift adders. For example, the first adder circuit 511 may be connected to a second shift adder SA2 and a third shift adder SA3. Likewise, the fifth adder circuit 515 may include a tenth shift register SA10 and an eleventh shift register SA11. Each of the 0-th to seventh adder circuits 510 to 517 may add values received from the shift adders.

In an embodiment, each of the 0-th to seventh adder circuits 510 to 517 may have a

calculation magnitude corresponding to an output value of the shift adder. For example, when the shift adder outputs a result of a 3-bit length, each of the 0-th to seventh adder circuits 510 to 517 may be a 3-bit adder, and an output thereof may have a 4-bit length. The 0-th to seventh adder circuits 510 to 517 may transfer calculation results to the tenth to thirteenth adder circuits 520 to 523.

The tenth to thirteenth adder circuits 520 to 523 may be adder circuits of a second layer. Each of the tenth to thirteenth adder circuits 520 to 523 may be connected to two of the adder circuits in the first layer. For example, the eleventh adder circuit 521 may be connected to the second adder circuit 512 and the third adder circuit 513 among the adder circuits of the first layer. For another example, the twentieth adder circuit 522 may be connected to the fourth shift adder 514 and the fifth adder circuit 515. Each of the tenth to thirteenth adder circuits 520 to 523 may add values received from the adder circuits of the first layer connected thereto.

In an embodiment, each of the 10-th to thirteenth adder circuits 520 to 523 may have a calculation magnitude corresponding to an output value of the adder circuit of the first layer. For example, when the output value of the adder circuits of the first layer has a 4-bit length, the tenth to thirteenth adder circuits 520 to 523 may be a 4-bit adder, and an output thereof may have a 5-bit length. A calculation result of each of the tenth to thirteenth adder circuits 520 to 523 may be transferred to the twentieth adder circuit 530 or the twenty-first adder circuit 531 connected thereto.

The twentieth adder circuit 530 and the twenty-first adder circuit 531 may be adder circuits of a third layer. Each of the twentieth adder circuit 530 and the twenty-first adder circuit 531 may be connected to two of the adder circuits in the second layer. For example, the twentieth adder circuit 530 may be connected to the tenth adder circuit 520 and the eleventh adder circuit 521 among the adder circuits of the second layer. Each of the twentieth adder circuit 530 and the twenty-first adder circuit 531 may add values received from the adder circuits of the second layer connected thereto.

In an embodiment, each of the twentieth adder circuit 530 and the twenty-first adder circuit 531 may have a calculation magnitude corresponding to an output value of the adder circuit of the second layer. For example, when the output value of the adder circuits of the second layer has a 5-bit length, the twentieth adder circuit 530 and the twenty-first adder circuit 531 may be a 5-bit adder, and an output thereof may have a 6-bit length. Each of the twentieth adder circuit 530 and twenty-first adder circuit 531 may transfer a calculation result to the overall adder circuit 540 connected thereto.

The overall adder circuit 540 may generate an overall output of the adder tree 500. The overall adder circuit 540 may be connected to the adder circuits of the third layer. For example, the overall adder circuit 540 may be connected to the twentieth adder circuit 530 and the twenty-first adder circuit 531 and may add output values of the twentieth adder circuit 530 and the twenty-first adder circuit 531. The overall adder circuit 540 may have a calculation magnitude corresponding to an output value of each of the twentieth adder circuit 530 and the twenty-first adder circuit 531. For example, when the output value of each of the twentieth adder circuit 530 and the twenty-first adder circuit 531 has a 6-bit length, the overall adder circuit 540 may be a 6-bit adder, and an output thereof may have a 7-bit length.

The overall adder circuit 540 may transfer the generated overall addition result to the partial-sum accumulation block 230 of FIG. 3. The adder tree 500 described with reference to FIG. 7 is provided as an example, and it should be construed that a structure of the adder tree 500 changes depending on the number of shift adders included in a cell group and the number of memory cell arrays included in a cell group.

FIG. 8 is a diagram illustrating an order of calculation operations which a memory cluster module of FIG. 3 performs, according to an embodiment of the present disclosure. An example of a calculation operation of a memory cluster module according to an embodiment of the present disclosure will be described with reference to FIGS. 3 to 8.

Referring to FIGS. 3 and 8, the memory cluster module 200 may support a calculation operation or may perform a calculation operation. In an embodiment, the memory cluster module 200 may support a weight calculation of stored data. For example, the memory cluster module 200 may support a calculation expressed by Equation 1 below.

$$S = {w}_{1} {α}_{1} + {w}_{2} {α}_{2} + {w}_{3} {α}_{3} + {w}_{4} {α}_{4} + … \qquad [ Equation 1 ]$$

In Equation 1 above, “S” may be a result of the calculation which the memory cluster module 200 performs, α₁, α₂, α₃, α₄ may be activation values stored in a memory cell array of FIG. 4A described with reference to FIGS. 5 and 6, ω₁, ω₂, ω₃, ω₄ may be weights respectively corresponding to activation values and respectively applied to the activation values. As the weight management block 210 of FIG. 3 manages weights in a log magnitude, the weight management block 210 may apply a weight to an activation value through a bit shift as much as a value which a weight indicates.

Referring to FIG. 8, as a weight is applied to activation values, the activation values are illustrated to correspond to a digit. Each of activation values illustrated in FIG. 8 and to be described with reference to FIG. 8 may include 8 digit bits, and the most significant bit (i.e., the 0-th bit) of each of the activation values may indicate a sign of an activation value. Accordingly, a weight multiplication calculation may be applied to a range from the first bit to the seventh bit. An A11-th activation value A11, a B11-th activation value B11, a C11-th activation value C11, and a D11-th activation value D11 may be stored in a memory cell array connected to a bitline, a bitline bar, and 0-th to thirty-first wordlines WL0 to WL31 in the same manner as described through the first memory cell array MCA1 of FIG. 6. That is, the first bit to the seventh bit of the A11-th activation value A11 may be stored in memory cells respectively connected to the first to seventh wordlines WL1 to WL7, and likewise, the remaining activation values may be connected to memory cells.

In FIG. 8, a weight of the A11-th activation value A11 may be “1”, a weight of the B11-th activation value B11 and the C11-th activation value C11 may be “4” (i.e., the second power of 2), and a weight of the D11-th activation value D11 may be “16” (i.e., the four power of 2). In an embodiment, the weight management block 210 may apply a weight to activation values, based on controlling an order in which the wordline decoder 320 of FIG. 4A reads data. For example, the weight management block 210 may allow the wordline decoder 320 of FIG. 4A to read bits coinciding with a digit. In FIG. 8, circular numbers under bits of weight values may indicate an order in which data are read, and parentheses under the bits may indicate word lines to which the turn-on voltage is to be applied to read data. For convenience, the description will be given under the condition that activation values of FIG. 8 are stored in the first memory cell array 311 and a sum calculation of bits is performed by the first shift adder 361.

In the memory block 300, as a bit corresponding to the first digit is the seventh bit A11[7] of the A11-th activation value A11, the wordline decoder 320 may apply the turn-on voltage to the seventh wordline WL7 such that the seventh bit A11[7] of the A11-th activation value A11 is transferred to the first shift adder 361. Because the number of bits of the first digit is “1”, the first shift adder 361 may perform an addition calculation by using only one bit and may generate a first initial calculation result. The first shift adder 361 may transfer the first initial calculation result to the adder tree 370, and the adder tree 370 may transfer the first initial calculation result to the partial-sum accumulation block 230 of FIG. 3.

After the calculation of the first digit is completed, the memory block 300 may compute bits of the second digit. The wordline decoder 320 may apply the turn-on voltage to the sixth wordline WL6 to read the sixth bit A11[6] of the A11-th activation value A11. Because any other value is absent from the second digit, the first shift adder 361 may generate a second initial calculation result by using only the corresponding bit. The first shift adder 361 may transfer the second initial calculation result to the partial-sum accumulation block 230 through the adder tree 370.

Next, the memory block 300 may compute bits of the third digit. The wordline decoder 320 may apply the turn-on voltage to the fifth wordline WL5 such that the fifth bit A11[5] of the A11-th activation value A11 is transferred to the first shift adder 361. Then, the wordline decoder 320 may apply the turn-on voltage to the fifteenth wordline WL15 such that the seventh bit B11[7] of the B11-th activation value B11 is transferred to the first shift adder 361. The first shift adder 361 may generate a third initial calculation result by summing the fifth bit A11[5] of the A11-th activation value A11 and the seventh bit B11[7] of the B11-th activation value B11 and may transfer the third initial calculation result to the partial-sum accumulation block 230 through the adder tree 370.

The wordline decoder 320 may apply the turn-on voltage to the twenty-third wordline WL23 such that the seventh bit C11[7] of the C11-th activation value C11 being the remaining value of the third digit is transferred to the first shift adder 361. The first shift adder 361 may generate a fourth initial calculation result by using only the seventh bit C11[7] of the C11-th activation value C11. The wordline decoder 320 may compute bits of the fourth digit in the same manner as the third digit.

The memory cluster module 200 may transfer a fifth initial calculation result, which is obtained by summing bits of the fourth digit, that is, the fourth bit A11[4] of the A11-th activation value A11 and the sixth bit B11[6] of the B11-th activation value B11, and a sixth initial calculation result, which is based on the sixth bit C11[6] of the C11-th activation value C11, to the partial-sum accumulation block 230.

After the calculation of the fourth digit is completed, the memory block 300 may compute bits of the fifth digit. The wordline decoder 320 may sequentially apply the turn-on voltage to the third wordline WL3 and the thirteenth wordline WL13 such that the third bit A11[3] of the A11-th activation value A11 and the fifth bit B11[5] of the B11-th activation value B11 are sequentially transferred to the first shift adder 361. The first shift adder 361 may generate a seventh initial calculation result by summing the third bit A11[3] of the A11-th activation value A11 and the fifth bit B11[5] of the B11-th activation value B11 and may transfer the seventh initial calculation result to the partial-sum accumulation block 230 through the adder tree 370. Next, the wordline decoder 320 may sequentially apply the turn-on voltage to the twenty-first wordline WL21 and the thirty-first wordline WL31 such that the fifth bit C11[5] of the C11-th activation value C11 and the seventh bit D11[7] of the D11-th activation value D11 are sequentially transferred to the first shift adder 361. The first shift adder 361 may generate an eighth initial calculation result by summing the fifth bit C11[5] of the C11-th activation value C11 and the seventh bit D11[7] of the D11-th activation value D11 and may transfer the eighth initial calculation result to the partial-sum accumulation block 230 through the adder tree 370.

Through a method which is the same as or similar to the above methods, the memory block 300 may add bits of each of the sixth digit to the tenth digit and may transfer generated initial calculation results to the partial-sum accumulation block 230. The partial-sum accumulation block 230 may add the received initial calculation results to coincide with the digit and may generate the overall calculation result. The memory cluster module 200 may perform the calculation described with reference to Equation 1 above, based on the operations described with reference to FIG. 8.

In FIG. 8, as the description is given based on the condition that the weight calculation is performed only in the first memory cell array 311, the adder tree 370 may not generate an initial calculation result which is based on the summation of any other initial calculation results. When data are stored in memory cell arrays of the first cell group CG1 except for the first memory cell array 311 and weight calculations are performed, the adder tree 370 may generate an intermediate calculation result by summing initial calculation results received simultaneously (or almost simultaneously) from shift adders respectively connected to the memory cell arrays. In this case, the adder tree 370 may transfer the intermediate calculation result to the partial-sum accumulation block 230. The partial-sum accumulation block 230 may sum intermediate calculation results to coincide with the digit. In an embodiment, the partial-sum accumulation block 230 may generate the overall calculation result, based on adding all the received intermediate calculation results of the digits to coincide with the digits. In an embodiment, the partial-sum accumulation block 230 may add intermediate calculation results for each digit while receiving intermediate calculation results and may generate the overall calculation result.

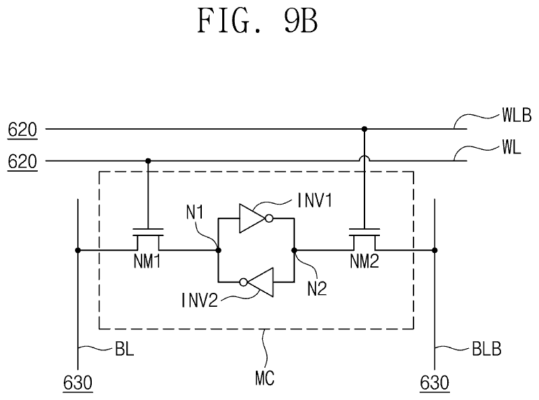

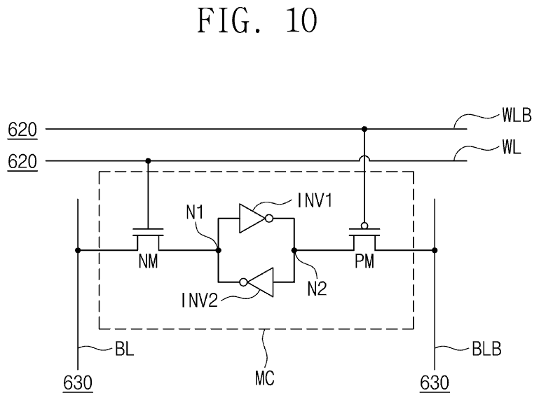

The operations of the memory cluster module 200 and the memory block 300 described with reference to FIG. 8, that is, the operation of applying a weight to activation values may be performed while changing a wordline targeted for the data read operation. As illustrated in FIG. 4B, because memory cells are connected to a bitline and a bitline bar, data of two cells may be read simultaneously, and thus, the calculation may be performed at faster speed. A memory block and a memory cluster module capable of providing a faster calculation by simultaneously reading bits stored in two cells will be described with reference to FIG. 9A and the following drawings.

FIG. 9A is a block diagram illustrating a memory block of FIG. 3, according to an embodiment of the present disclosure. A memory block 600 may be one of the memory blocks 220 of FIG. 3. FIG. 9B is a circuit diagram illustrating one memory cell included in memory cell arrays of FIG. 9A, according to an embodiment of the present disclosure.

Referring to FIG. 9A, the memory block 600 may include memory cell arrays 611 and 612, a wordline decoder 620, a column decoder 630, a controller 640, a shift adder controller 650, shift adders 661 and 662, and an adder tree 670.

The memory cell arrays 611 and 612 may store data. In an embodiment, the memory cell arrays 611 and 612 may include a plurality of memory cells. The memory cell arrays 611 and 612 may be connected to a plurality of word lines and a plurality of wordline bars and may be connected to a bitline and a bitline bar. For example, the first memory cell array 611 may be connected to first wordlines WL1s and first wordline bars WLB1s and may be connected to the first bitline BL1 and the first bitline bar BLB1. The second memory cell array 612 may be connected to second wordlines WL2s and second wordline bars WLB2s and may be connected to the first bitline BL1 and the first bitline bar BLB1.

A structure of one memory cell MC included in the memory cell arrays 611 and 612 will be described with reference to FIG. 9B. Referring to FIG. 9B, the memory cell MC may include the first inverter INV1, the second inverter INV2, the first n-type metal-oxide-semiconductor (NMOS) transistor NM1, and the second NMOS transistor NM2. The memory cell MC may be a dual wordline cell.

The first inverter INV1 may include the input terminal connected to the first node N1 and the output terminal connected to the second node N2. A logic level of the first node N1 and a logic level of the second node N2 may be opposite to each other. For example, when the first node N1 has the logic high level, the logic level of the second node N2 may have the logic low level. The second inverter INV2 may include the input terminal connected to the second node N2 and the output terminal connected to the first node N1.

The first NMOS transistor NM1 may be connected between the first node N1 and the bitline BL and may include the gate node connected to the wordline WL. The second NMOS transistor NM2 may be connected between the second node N2 and the bitline bar BLB and may include the gate node connected to the wordline bar WLB. When the turn-on voltage is applied to the wordline WL, voltage levels of the first node N1 and the bitline BL may be equalized. When the turn-on voltage is applied to the wordline bar WLB, voltage levels of the second node N2 and the bitline bar BLB may be equalized.

That is, in a memory cell array including the memory cell MC of FIG. 9B, data of a first memory cell may be read through the wordline WL and the bitline BL, and data of a second memory cell may be read through the wordline bar WLB and the bitline bar BLB. Returning to FIG. 9A, the wordline decoder 620 may select a wordline or a wordline bar to which the turn-on voltage is to be applied. In an embodiment, the wordline decoder 620 may operate under control of the controller 640. For example, under control of the controller 640, the wordline decoder 620 may apply the turn-on voltage to a wordline of memory cells targeted for the read operation or the write operation.

In an embodiment, the wordline decoder 620 may operate under control of the weight management block 210 of FIG. 2. For example, the wordline decoder 620 may apply the turn-on voltage to a wordline or a wordline bar depending on a weight of the weight management block 210. The wordline decoder 620 may allow a weight to be applied to data of the memory cell arrays 611 and 612, based on the control of the weight management block 210.

The column decoder 630 may be connected to the bitline BL and the bitline bar BLB of the memory cell arrays 611 and 612. The column decoder 630 may provide data to be written in a memory cell of the memory cell arrays 611 and 612 or may receive data read from a memory cell of the memory cell arrays 611 and 612. In an embodiment, the column decoder 630 may operate under control of the controller 640. In an embodiment, the column decoder 630 may receive data to be written through the cluster interface block 250 of FIG. 2 or may transfer read data to the cluster interface block 250 of FIG. 2. For example, under control of the controller 640, the column decoder 630 may transfer data to be written in memory cells of the memory cell arrays 611 and 612 to the memory cells through the bitline BL and the bitline bar BLB.

The controller 640 may control the data write operation or the data read operation of the memory cell arrays 611 and 612. In an embodiment, the controller 640 may control the memory cell arrays 611 and 612, based on controlling the wordline decoder 620 and the column decoder 630. In an embodiment, the controller 640 may control the wordline decoder 620 or the column decoder 630, in response to a command/address received from the cluster interface block 250 of FIG. 3.

The shift adder controller 650 may control the shift adders 661 and 662. In an embodiment, the shift adder controller 650 may operate under control of the weight management block 210 of FIG. 3. For example, the shift adder controller 650 may control the shift adders 661 and 662, based on a control signal received from the weight management block 210.

In an embodiment, the shift adder controller 650 may provide the shift adder 661 with sign information of a calculation result of the shift adder 661 and may provide the shift adder 662 with sign information of a calculation result of the shift adder 662. The shift adder controller 650 may determine signs to be provided to the shift adders 661 and 662, based on sign information provided from the weight management block 210. In an embodiment, the most significant bit (MSB) of each of a weight and data may express a sign. The weight management block 210 may transfer the sign information to the shift adder controller 650, based on MSBs of a weight and data to be input to each of the shift adders 661 and 662, and the shift adder controller 650 may provide sign information corresponding to each of the shift adders 661 and 662, based on the received sign information. The sign information may include a sign of data including a first bit received through the first bitline BL1 and a sign of a weight (or a sign of the multiplication of the data and the weight) and a sign of data including a second bit received through the first bitline bar BLB1 and a sign of a weight (or a sign of the multiplication of the data and the weight).

The shift adders 661 and 662 may be connected to the first bitline BL1 and the first bitline bar BLB1 and may perform addition of data. In an embodiment, the shift adders 661 and 662 may sum two bits which are sequentially read. In an embodiment, when the number of bits corresponding to a digit is only one, the shift adders 361 and 362 may add the corresponding bit and “0”. For example, when the number of bits corresponding to a digit is only “1”, the shift adders 661 and 662 may generate a result of adding the corresponding bit and “0” and a sign, under control of the shift adder controller 650.

In an embodiment, the shift adders 661 and 662 may express a negative output signal in a 2's complement form. For example, the shift adders 661 and 662 may generate an initial calculation result of a 3-bit length, based on sign information and a result of summing two bits received (e.g., simultaneously or almost simultaneously) through the first bitline BL1 and the first bitline bar BLB1. For example, when a multiplication of a weight and data which the first shift adder 661 computes is positive and all the sequentially received bits are logic “1”, the first shift adder 661 may output a logical value of “010”. For another example, when a multiplication of a weight and data which the first shift adder 661 computes is negative and the sequentially received bits are logic “1” and logic “0”, the first shift adder 661 may output a logical value of “111”.

The calculation results of the shift adders 661 and 662 may be transferred to the adder tree 670. In an embodiment, the shift adders 661 and 662 may be respectively allocated to the memory cell arrays 611 and 612. For example, the first shift adder 661 may be allocated to the first memory cell array 611, and the second shift adder 662 may be allocated to the second memory cell array 612. That is, the first shift adder 661 may add bits read from the first memory cell array 611, and the second shift adder 662 may add bits read from the second memory cell array 612.

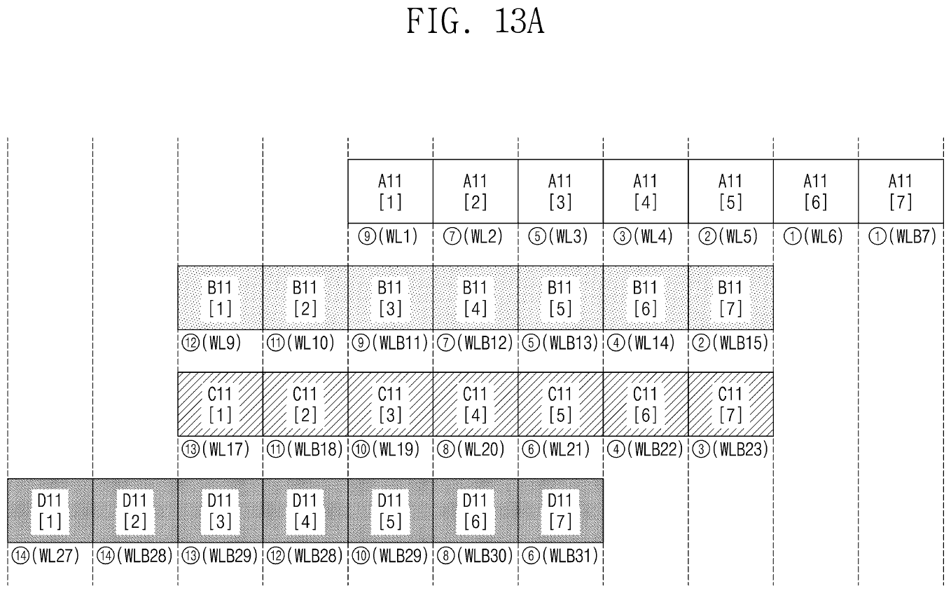

In an embodiment, the shift adders 661 and 662 may shift left one of inputs and may add a shifting result and the other thereof. For example, the first shift adder 661 may sum a value obtained by shifting left a first input received from the first bitline BL1 as much as one bit and a second input received from the first bitline bar BLB1. The shift adders 661 and 662 may shift left one of inputs under control of the shift adder controller 650. A structure of the shift adders 661 and 662 will be described in detail with reference to FIG. 12.

The adder tree 670 may generate an intermediate calculation result by adding calculation results received from the shift adders 661 and 662. In an embodiment, the adder tree 670 may transfer the generated intermediate calculation result to the partial-sum accumulation block 230 of FIG. 3. For example, the adder tree 670 may generate an intermediate calculation result by adding a first calculation result received from the first shift adder 661 and a second calculation result received from the second shift adder 662 and may transfer the intermediate calculation result to the partial-sum accumulation block 230 of FIG. 3.

The adder tree 670 may be allocated for each cell group. The adder tree 670 may generate an intermediate calculation result by adding all calculation results received from shift adders included in a cell group. For example, when the first cell group CG1 includes 16 memory cell arrays and 16 shift adders respectively corresponding to the 16 memory cell arrays, the adder tree 670 may sum all of 16 initial calculation results received from the 16 shift adders so as to be transferred to the partial-sum accumulation block 230. A detailed structure of the adder tree 670 is the same as the structure described with reference to FIG. 7.

Referring to FIG. 3, the partial-sum accumulation block 230 may arrange a calculation result received from the adder tree 670 so as to coincide with a digit. In an embodiment, the partial-sum accumulation block 230 may arrange and add calculation results received from the adder tree 670 so as to coincide with a digit. For example, when the partial-sum accumulation block 230 receives a first calculation result and a second calculation result of a digit immediately above the first intermediate calculation result from the adder tree 670, the partial-sum accumulation block 230 may perform an accumulation calculation by adding the first calculation result and a doubled value of the second calculation result.

The memory block 600 described with reference to FIG. 9A is provided as an example, and the scope of the present disclosure should not be construed as being limited thereto. The first cell group CG1 may additionally include memory cell arrays and shift adders corresponding to the memory cell arrays, and wordlines connected to each of the memory cell arrays may be additionally connected to the wordline decoder 620. Alternatively, the memory block 600 may further include additional cell groups being the same as the first cell group CG1, and each of the additional cell groups may include memory cell arrays, shift adders corresponding to the memory cell arrays, and an adder tree. For example, the memory block 600 may include 32 cell groups, each of the 32 cell groups may include 16 memory cell arrays, 16 shift adders corresponding to the 16 memory cell arrays, and an adder tree, and each of the 16 memory cell arrays may include 32 memory cells connected to 32 wordlines and 32 wordline bars (in this case, the wordline decoder 620 may be connected to 512 wordlines and 512 wordline bars).

FIG. 10 is a circuit diagram illustrating a memory cell included in memory cell arrays of FIG. 9A according to an embodiment of the present disclosure. Referring to FIG. 10, the memory cell MC may include the first inverter INV1, the second inverter INV2, an NMOS transistor NM, and a p-type metal-oxide-semiconductor (PMOS) transistor PM. The memory cell MC may be a dual wordline cell.

The first inverter INV1 may include the input terminal connected to the first node N1 and the output terminal connected to the second node N2. A logic level of the first node N1 and a logic level of the second node N2 may be opposite to each other. For example, when the first node N1 has the logic high level, the logic level of the second node N2 may have the logic low level. The second inverter INV2 may include the input terminal connected to the second node N2 and the output terminal connected to the first node N1.

The NMOS transistor NM may be connected between the first node N1 and the bitline BL and may include the gate node connected to the wordline WL. The PMOS transistor PM may be connected between the second node N2 and the bitline bar BLB and may include the gate node inverse connected to the wordline bar WLB. When a first turn-on voltage is applied to the wordline WL, voltage levels of the first node N1 and the bitline BL may be equalized. When a second turn-on voltage is applied to the wordline bar WLB, voltage levels of the second node N2 and the bitline bar BLB may be equalized.

Referring to FIGS. 9B and 10, the memory cell MC of FIG. 10 may be the same as the memory cell MC of FIG. 9B except that different types of transistors are connected between the second node N2 and the bitline bar BLB. The memory cell MC of FIG. 10 may reduce power consumption by using a PMOS transistor between the bitline bar BLB and the second node N2 at which an inverse level of stored data is stored. As the number of data of logic “0” stored in the memory cells MC increases, power consumption according to the data read operation of the memory block 600 including the memory cells MC of FIG. 10 may be reduced (the reason is that the second node N2 has the voltage level corresponding to logic “1” when logic “0” is stored in the memory cell MC).

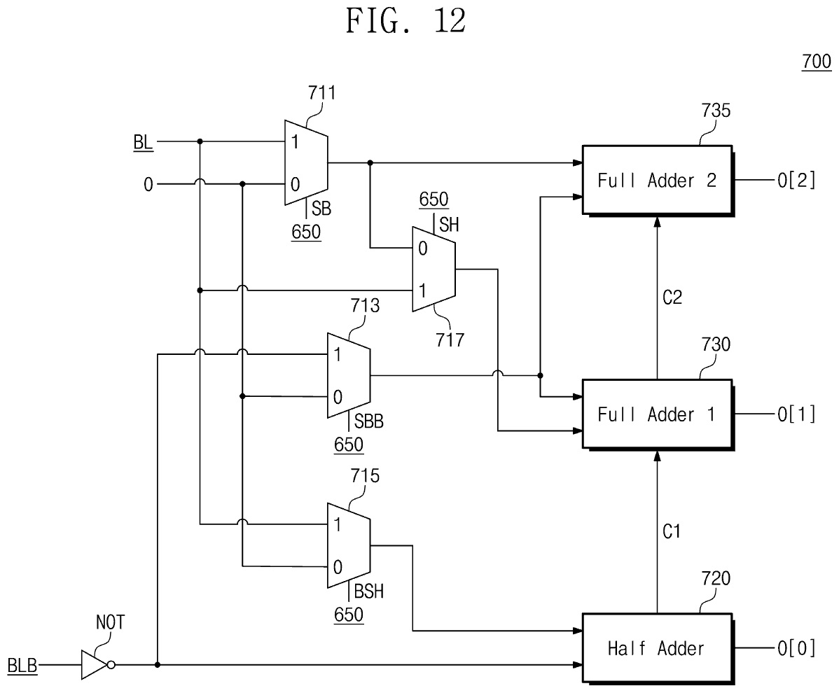

FIG. 11 is a diagram illustrating a calculation operations of a memory cluster module of FIG. 3, according to an embodiment of the present disclosure. An example of a calculation operation of a memory cluster module according to an embodiment of the present disclosure will be described with reference to FIGS. 5 to 7 and 9A to 11.

Referring to FIG. 11, as a weight is applied to activation values, the activation values are illustrated to correspond to a digit as illustrated in FIG. 8. Each of activation values illustrated in FIG. 11 and to be described with reference to FIG. 11 may include 8 digit bits, and the most significant bit (i.e., the 0-th bit) of each of the activation values may indicate a sign of an activation value. Accordingly, a weight multiplication calculation may be applied to a range from the first bit to the seventh bit. The A11-th activation value A11, the B11-th activation value B11, the C11-th activation value C11, and the D11-th activation value D11 may be stored in a memory cell array connected to a bitline, a bitline bar, 0-th to thirty-first wordlines WL0 to WL31, and 0-th to thirty-first wordline bars WLB0 to WLB31 in the same manner as described through the first memory cell array MCA1 of FIG. 6. That is, the first to seventh bits A11[1] to A11[7] of the A11-th activation value A11 may be stored in memory cells connected to the first to seventh wordlines WL1 to WL7 and the first to seventh wordline bars WLB1 to WLB7, and likewise, the remaining activation values may be connected to memory cells (e.g., the second bit A11[2] of the A11-th activation value A11 may be stored in the memory cell connected to the second wordline WL2 and the second wordline bar WLB2). For another example, the first to seventh bits C11[1] to C11[7] of the C11-th activation value C11 may be stored in memory cells connected to the seventeenth to twenty-third wordlines WL17 to WL23 and the seventeenth to twenty-third wordline bars WLB17 to WLB23.

In FIG. 11, a weight of the A11-th activation value A11 may be “1”, a weight of the B11-th activation value B11 and the C11-th activation value C11 may be “4” (i.e., the second power of 2), and a weight of the D11-th activation value D11 may be “16” (i.e., the four power of 2). In an embodiment, the weight management block 210 may apply a weight to activation values, based on controlling the wordline decoder 620 of FIG. 9A, that is, an order in which data are read. For example, the weight management block 210 may allow the wordline decoder 620 of FIG. 9A to read bits coinciding with a digit. In FIG. 11, circular numbers under bits of weight values may indicate an order in which data are read, and parentheses under the bits may indicate a wordline or a wordline bar to which the turn-on voltage is to be applied to read data. For convenience, the description will be given based on the first memory cell array 611, the first shift adder 661, and the adder tree 670 of FIG. 9A.

Referring to FIG. 9A, the wordline decoder 620 may apply the turn-on voltage to the seventh wordline WL7 such that the seventh bit A11[7] of the A11-th activation value A11 is read and is then transferred to the first shift adder 661 connected to the first memory cell array 611. Because the number of bits of the first digit is “1”, the first shift adder 661 may generate a first initial calculation result based on the seventh bit A11[7] of the A11-th activation value A11. The first shift adder 661 may transfer the first initial calculation result to the adder tree 670, and the adder tree 670 may transfer the first initial calculation result to the partial-sum accumulation block 230 of FIG. 3.

After the calculation of the first digit is completed, the memory block 600 may compute bits of the second digit. The wordline decoder 620 may apply the turn-on voltage to the sixth wordline WL6 to read the sixth bit A11[6] of the A11-th activation value A11. Because any other value is absent from the second digit, the first shift adder 661 and the adder tree 670 may generate a second initial calculation result based on the sixth bit A11[6] of the A11-th activation value A11 so as to be transferred to the partial-sum accumulation block 230.

Next, the memory block 600 may compute bits of the third digit. The wordline decoder 620 may apply the turn-on voltage to the fifth wordline WL5 and the fifteenth wordline WLB15 such that the fifth bit A11[5] of the A11-th activation value A11 and the seventh bit B11[7] of the B11-th activation value B11 are transferred to the first shift adder 661 (e.g., simultaneously or almost simultaneously). In this case, the first shift adder 661 may receive the fifth bit A11[5] of the A11-th activation value A11 through the first bitline BL1 and may receive the seventh bit B11[7] of the B11-th activation value B11 through the first bitline bar BLB1. The first shift adder 661 may generate a third initial calculation result by summing the fifth bit A11[5] of the A11-th activation value A11 and the seventh bit B11[7] of the B11-th activation value B11 and may transfer the third initial calculation result to the partial-sum accumulation block 230 through the adder tree 670. The adder tree 670 may transfer the third initial calculation result to the partial-sum accumulation block 230.

The wordline decoder 620 may apply the turn-on voltage to the twenty-third wordline WL23 such that the seventh bit C11[7] of the C11-th activation value C11 being the remaining value of the third digit is transferred to the first shift adder 661. The first shift adder 661 may transfer a fourth initial calculation result generated based on the seventh bit C11[7] of the C11-th activation value C11 to the adder tree 670. The adder tree 670 may transfer the fourth initial calculation result to the partial-sum accumulation block 230. The order of reading the bits of the third digit is provided as an example, and the present disclosure should not be construed as being limited thereto.

The wordline decoder 620 may compute bits of the fourth digit in the same manner as the third digit. The memory block 600 may transfer a fifth initial calculation result, which is obtained by summing bits of the fourth digit, that is, the fourth bit A11[4] of the A11-th activation value A11 and the sixth bit B11[6] of the B11-th activation value B11, and a sixth initial calculation result, which is generated based on the sixth bit C11[6] of the C11-th activation value C11, to the partial-sum accumulation block 230.

After the calculation of the fourth digit is completed, the memory block 600 may compute bits of the fifth digit. The wordline decoder 620 may apply the turn-on voltage to the third wordline WL3 and the thirteenth wordline WL13 such that the third bit A11[3] of the A11-th activation value A11 and the fifth bit B11[5] of the B11-th activation value B11 are transferred to the first shift adder 661 (e.g., simultaneously or almost simultaneously). The first shift adder 661 may generate a seventh initial calculation result by summing the third bit A11[3] of the A11-th activation value A11 and the fifth bit B11[5] of the B11-th activation value B11 and may transfer the seventh initial calculation result to the partial-sum accumulation block 230 through the adder tree 670. The adder tree 670 may transfer the seventh initial calculation result to the partial-sum accumulation block 230.

Next, the wordline decoder 620 may apply the turn-on voltage to the twenty-first wordline WL21 and the thirty-first wordline WLB31 such that the fifth bit C11[5] of the C11-th activation value C11 and the seventh bit D11[7] of the D11-th activation value D11 are transferred to the first shift adder 661 (e.g., simultaneously or almost simultaneously). The first shift adder 661 may generate an eighth initial calculation result by summing the fifth bit C11[5] of the C11-th activation value C11 and the seventh bit D11[7] of the D11-th activation value D11 and may transfer the eighth initial calculation result to the partial-sum accumulation block 230 through the adder tree 670. The adder tree 670 may transfer the eighth initial calculation result to the partial-sum accumulation block 230.

Through a method which is the same as or similar to the above methods, the memory cluster module 200 may sum bits of sixth digit to the tenth digit by using two bits (or only one bit) for each digit and may transfer generated initial calculation results to the partial-sum accumulation block 230. The partial-sum accumulation block 230 may generate the overall calculation result, based on the initial calculation results. In an embodiment, the partial-sum accumulation block 230 may generate the overall calculation result, based on adding all the received intermediate calculation results of the first to tenth digits to coincide with the digits. In an embodiment, the partial-sum accumulation block 230 may add initial calculation results for each digit simultaneously while receiving initial calculation results and may generate the overall calculation result. The memory cluster module 200 may perform the calculation described with reference to Equation 1 above, based on the operations described with reference to FIG. 11.

The operations of the memory cluster module 200 and the memory block 600 described with reference to FIG. 11, that is, the operation of applying a weight to activation values may be performed while changing a wordline or a wordline bar targeted for the data read operation. The memory block 300 of FIG. 8 may read data to coincide with a weight through 28 read operations, while the memory block 600 of FIG. 11 may read data to coincide with a weight through 18 read operations, based on a dual wordline cell. Unlike the operation of the memory cluster module 200 described with reference to FIG. 8, according to the operation of the memory cluster module 200 described with reference to FIG. 11, because shift adders are capable of operating such that two inputs are received at a time, a time taken for weight calculation may be decreased compared to the operation of the memory cluster module 200 described with reference to FIG. 8.

In FIG. 11, as the description is given based on the condition that the weight calculation is performed only in the first memory cell array 611, the adder tree 670 may not generate an intermediate calculation result which is based on the summation of any other initial calculation results. When data are stored in memory cell arrays of the first cell group CG1 except for the first memory cell array 611 and weight calculations are performed, the adder tree 670 may generate an intermediate calculation result by summing initial calculation results received simultaneously (or almost simultaneously) from shift adders respectively connected to the memory cell arrays. In this case, the adder tree 670 may transfer the intermediate calculation result to the partial-sum accumulation block 230. The partial-sum accumulation block 230 may sum intermediate calculation results to coincide with the digit. In an embodiment, the partial-sum accumulation block 230 may generate the overall calculation result, based on adding all the received intermediate calculation results of the digits to coincide with the digits. In an embodiment, the partial-sum accumulation block 230 may add intermediate calculation results for each digit while receiving intermediate calculation results and may generate the overall calculation result.

In FIG. 11, in the case of some digits, it is impossible to read two bits when only one bit remains. In this case, the memory block 600 is incapable of fully using the characteristic of the dual wordline cell. Even though only one bit remains at a digit, there are required a structure and an operation which allow a shift adder to receive two bits simultaneously by fully using the dual wordline cell. A shift adder which is capable of receiving two bits continuously will be described with reference to FIG. 12.

FIG. 12 is a circuit diagram illustrating a shift adder of FIG. 9A, according to an embodiment of the present disclosure. A shift adder 700 may be one of the shift adders 661 and 662 of FIG. 9A. Referring to FIG. 12, the shift adder 700 may include a first multiplexer 711, a second multiplexer 713, a third multiplexer 715, a fourth multiplexer 717, a half adder 720, a first full adder 730, and a second full adder 735. The shift adder 700 according to an embodiment of the present disclosure will be described with reference to FIGS. 9A and 12.

The first multiplexer 711 may include a first input terminal connected to the bitline BL and a second input terminal to which logic “0” is input. In an embodiment, the first multiplexer 711 may select an output in response to a control signal of the shift adder controller 650 of FIG. 9A. For example, the first multiplexer 711 may operate in response to a bitline sign signal SB received from the shift adder controller 650. The first multiplexer 711 may transfer an output signal to the fourth multiplexer 717 and the second full adder 735.

The bitline sign signal SB may indicate a sign of a multiplication between an activation value output through the bitline BL and a weight to be applied to the activation value. In an embodiment, the shift adder controller 650 of FIG. 9A may generate the bitline sign signal SB, based on the comparison of an MSB value of an activation value including a bit output through the bitline BL and an MSB value of a weight to be applied to the activation value. In an embodiment, when the sign of the multiplication between the activation value and the weight to be applied to the activation value is negative, the bitline sign signal SB may be of logic “1”. In contrast, when the sign of the multiplication between the activation value and the weight to be applied to the activation value is positive, the bitline sign signal SB may be of logic “0”. When the bitline sign signal SB is of logic “1”, the first multiplexer 711 may output a signal input to the first input terminal; when the bitline sign signal SB is of logic “0”, the first multiplexer 711 may output a signal input to the second input terminal.

A NOT gate NOT may generate an output signal obtained by inverting an input signal. For example, when logic “0” is received, the NOT gate NOT may output logic “1”; in contrast, when logic “1” is received, the NOT gate NOT may output logic “0”. In an embodiment, the NOT gate NOT may generate an output obtained by inverting the level of the bitline bar BLB. For example, when the level received through the bitline bar BLB corresponds to logic “1”, the NOT gate NOT may output logic “0” (in other words, because data output through the bitline bar BLB are complementary to data stored in a memory cell, the data stored in the memory cell may be input to the shift adder 700 through the NOT gate NOT). The NOT gate NOT may transfer the output signal to the second multiplexer 713 and the half adder 720.

The second multiplexer 713 may include a first input terminal connected to an output terminal of the NOT gate NOT and a second input terminal to which logic “0” is input. In an embodiment, the second multiplexer 713 may select an output in response to a control signal of the shift adder controller 650 of FIG. 9A. For example, the second multiplexer 713 may operate in response to a bitline sign signal bar SBB received from the shift adder controller 650. The second multiplexer 713 may transfer an output signal to the first full adder 730 and the second full adder 735.

The bitline sign signal bar SBB may indicate a sign of a multiplication between an activation value output through the bitline bar BLB and a weight to be applied to the activation value. In an embodiment, the shift adder controller 650 of FIG. 9A may generate the bitline sign signal bar SBB, based on the comparison of an MSB value of an activation value including a bit output through the bitline bar BLB and an MSB value of a weight to be applied to the activation value. In an embodiment, when the sign of the multiplication between the activation value and the weight to be applied to the activation value is positive, the bitline sign signal bar SBB may be of logic “1”. In contrast, when the sign of the multiplication between the activation value and the weight to be applied to the activation value is negative, the bitline sign signal bar SBB may be of logic “0”. When the bitline sign signal bar SBB is of logic “1”, the second multiplexer 713 may output a signal input to the first input terminal; when the bitline sign signal bar SBB is of logic “0”, the second multiplexer 713 may output a signal input to the second input terminal.

The third multiplexer 715 may include a first input terminal connected to the bitline BL and a second input terminal to which logic “0” is input. In an embodiment, the third multiplexer 715 may select an output in response to a control signal of the shift adder controller 650 of FIG. 9A. For example, the third multiplexer 715 may operate in response to a bar shift signal BSH received from the shift adder controller 650. The third multiplexer 715 may transfer an output signal to the half adder 720.

A shift signal SH may refer to a signal for shifting left a first input of the shift adder 700 as much as one bit. For example, when the shift adder 700 operates in response to the shift signal SH of logic “1”, the shift adder 700 may add a value, which is obtained by shifting left the first input as much as one bit and a bit received as a second input, and may generate an output signal. The bar shift signal BSH may be an inverted version of the shift signal SH. For example, when the shift signal SH is of logic “1”, the bar shift signal BSH may be of logic “0”. When the bar shift signal BSH is of logic “1”, the third multiplexer 715 may output a signal input to the first input terminal; when the bar shift signal BSH is of logic “0”, the third multiplexer 715 may output a signal input to the second input terminal.

The fourth multiplexer 717 may include a first input terminal connected to the bitline BL and a second input terminal connected to an output terminal of the first multiplexer 711. In an embodiment, the fourth multiplexer 717 may select an output under control of the shift adder controller 650 of FIG. 9A. For example, the fourth multiplexer 717 may operate in response to the shift signal SH received from the shift adder controller 650. In detail, for example, when the shift signal SH is of logic “1”, the fourth multiplexer 717 may output a signal input through the first input terminal; when the shift signal SH is of logic “0”, the fourth multiplexer 717 may output a signal input through the second input terminal. The fourth multiplexer 717 may transfer an output signal to the first full adder 730.

The half adder 720 may add input signals. In an embodiment, the half adder 720 may add two bits. For example, the half adder 720 may receive an output bit of the NOT gate NOT and an output bit of the third multiplexer 715 and may output a result of summing the received output bits. The half adder 720 may generate a 2-bit output as a calculation result, the least significant bit of the 2-bit output may be the least significant bit O[0] of an output value of the shift adder 700, and the most significant bit of the 2-bit output may be a first carry signal C1 to be transferred to the first full adder 730. The half adder 720 may transfer the first carry signal C1 to the first full adder 730.

The first full adder 730 may add input signals. In an embodiment, the first full adder 730 may add three bits. For example, the first full adder 730 may receive the first carry signal C1, the output signal of the second multiplexer 713, and the output signal of the fourth multiplexer 717 and may add all the received signals. The first full adder 730 may output two bits, the least significant bit of the two bits may be the least significant bit O[1] of the output value of the shift adder 700, and the most significant bit of the two bits may be a second carry signal C2 to be transferred to the second full adder 735. The first full adder 730 may transfer the second carry signal C2 to the second full adder 735.

The second full adder 735 may add input signals. In an embodiment, the second full adder 735 may add three bits. The second full adder 735 may generate a 1-bit output. When the 2-bit output is generated as an addition result, the second full adder 735 may output only the least significant bit as an output. The output signal of the second full adder 735 may be the most significant bit O[2] of the output signal of the shift adder 700.

The shift adder 700 may generate the 3-bit output, based on the structure described with reference to FIG. 12. The most significant bit O[2] of the 3-bit output may indicate a sign of the output signal. For example, the case where the most significant bit O[2] is “0” may indicate that the output signal is positive, and a magnitude of the output signal may be determined depending on an intermediate bit O[1] and the least significant bit O[0]. In an embodiment, that the output signal is negative may be expressed in a 2's complement form. Depending on the structure described with reference to FIG. 12, the shift adder 700 may shift left one of the input bits as much as one bit and may use a shifting result for addition.

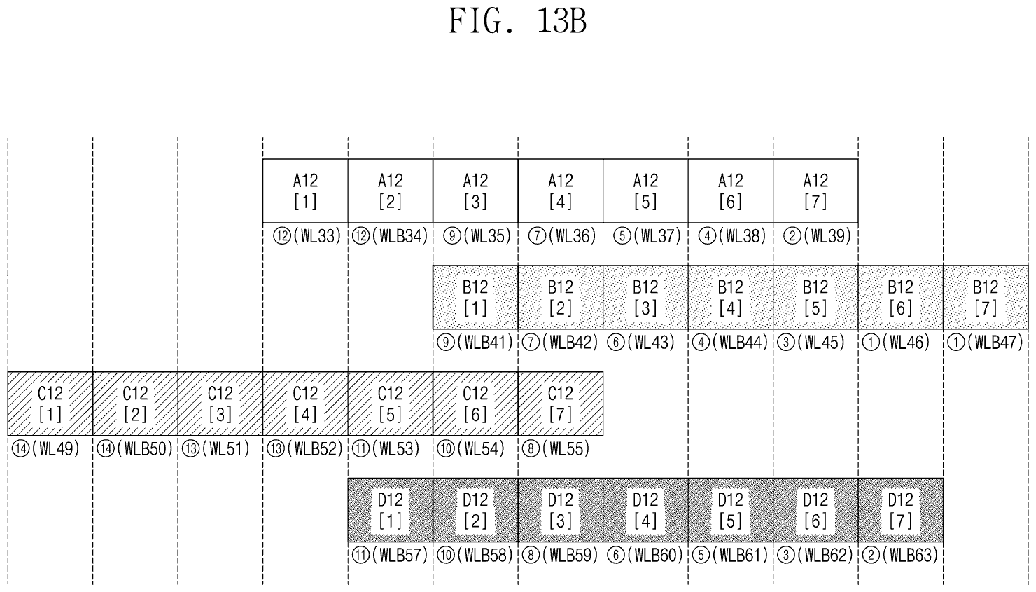

As illustrated in FIG. 11, even in the case where one bit remains for each digit, the shift adder 700 may shift a bit of a next digit and may use a shifting result for addition. Accordingly, the efficiency of the addition operation of the memory block 600 may be improved. In FIG. 12, in an embodiment, the description is given as the shift adder 700 shifts left a bit received through the bitline BL as much as one bit in response to the shift signal SH, but the present disclosure is not limited thereto. For example, an embodiment in which a signal received through the bitline bar BLB is shifted left as much as one bit should also be construed as belonging to the scope of the present disclosure. A calculation operation of the memory cluster module 200 including the memory block 600 where the shift adder 700 of FIG. 12 is included will be described with reference to FIGS. 13A and 13B.

FIGS. 13A and 13B are diagrams illustrating examples of a calculation operation of a memory cluster module of FIG. 3, according to an embodiment of the present disclosure. A calculation operation of the memory cluster module 200 according to an embodiment of the present disclosure will be described with reference to FIGS. 3, 5, 6, 7, 9A to 10, 12, 13A, and 13B. Magnitudes of an activation value and a to-be-applied weight to be described with reference to FIG. 13A are the same as those described with reference to FIGS. 8 to 11. In FIGS. 13A and 13B, circular numbers under bits may indicate an order in which bits are read, and parentheses under the bits may indicate a wordline or a wordline bar to which the turn-on voltage is to be applied. For convenience, the description will be given based on the condition that activation values are stored in the first memory cell array MCA1 of FIG. 13A, but the present disclosure is not limited thereto.

In FIG. 13A, the memory block 600 may be configured to transfer two bits to be computed to the shift adder 700. The memory block 600 may be configured to compute bits of the first digit and the second digit. The wordline decoder 620 may apply the turn-on voltage to the sixth wordline WL6 and the seventh wordline bar WLB7 of the first memory cell array 611 such that the sixth bit A11[6] of the A11-th activation value A11 and the seventh bit A11[7] of the A11-th activation value A11 are read. The sixth bit A11[6] of the A11-th activation value A11 and the seventh bit A11[7] of the A11-th activation value A11 may be transferred to the first shift adder 661 (e.g., simultaneously or almost simultaneously). In this case, because bits of different digits are read, the shift adder controller 650 may set the shift signal SH to logic “1”. The first shift adder 661 may generate a first initial calculation result by adding the sixth bit A11[6] of the A11-th activation value A11 and the seventh bit A11[7] of the A11-th activation value A11. The first shift adder 661 may transfer the first initial calculation result to the adder tree 670, and the adder tree 670 may transfer the first initial calculation result to the partial-sum accumulation block 230.

Next, the memory block 600 may compute bits of the third digit. The wordline decoder 620 may apply the turn-on voltage to the fifth wordline WL5 and the fifteenth wordline bar WLB 15 such that the fifth bit A11[5] of the A11-th activation value A11 and the seventh bit B11[7] of the B11-th activation value B11 are read. The fifth bit A11[5] of the A11-th activation value A11 and the seventh bit B11[7] of the B11-th activation value B11 may be transferred to the first shift adder 661 (e.g., simultaneously or almost simultaneously). As bits of the same digit are read, the shift adder controller 650 may set the shift signal SH to logic “0”. The first shift adder 661 may generate a second initial calculation result by summing the fifth bit A11[5] of the A11-th activation value A11 and the seventh bit B11[7] of the B11-th activation value B11. The first shift adder 661 may transfer the second initial calculation result to the adder tree 670, and the adder tree 670 may transfer the second initial calculation result to the partial-sum accumulation block 230.

Next, the memory block 600 may add one bit of the third digit and one bit of the fourth digit being a next digit. The wordline decoder 620 may apply the turn-on voltage to the fourth wordline WL4 and the twenty-third wordline bar WLB23 of the first memory cell array 611 such that the fourth bit A11[4] of the A11-th activation value A11 and the seventh bit C11[7] of the C11-th activation value C11 are read. The fourth bit A11[4] of the A11-th activation value A11 and the seventh bit C11[7] of the C11-th activation value C11 may be transferred to the first memory cell array 611 (e.g., simultaneously or almost simultaneously). In this case, because bits of different digits are read, the shift adder controller 650 may set the shift signal SH to logic “1”. The first shift adder 661 may generate a third initial calculation result by adding the fourth bit A11[4] of the A11-th activation value A11 and the seventh bit C11[7] of the C11-th activation value C11. The first shift adder 661 may transfer the third initial calculation result to the adder tree 670, and the adder tree 670 may transfer the third initial calculation result to the partial-sum accumulation block 230.

As in the above manner of generating the second initial calculation result, the memory block 600 may generate a fourth initial calculation result by summing the sixth bit B11[6] of the B11-th activation value B11 and the sixth bit C11[6] of the C11-th activation value C11 and may transfer the fourth initial calculation result to the partial-sum accumulation block 230. As in the above manner of generating the second initial calculation result, the memory block 600 may generate fifth to eleventh initial calculation results and may transfer the fifth to eleventh initial calculation results to the partial-sum accumulation block 230.

As in the above manner of generating the first initial calculation result, the memory block 600 may generate a twelfth initial calculation result by reading and adding the first bit B11[1] of the B11-th activation value B11 and the fourth bit D11[4] of the D11-th activation value D11. As in the above manner of generating the second initial calculation result, the memory block 600 may generate a thirteenth initial calculation result and may transfer the thirteenth initial calculation result to the partial-sum accumulation block 230. Finally, as in the above manner of generating the first initial calculation result, the memory block 600 may generate a fourteenth initial calculation result and may transfer the fourteenth initial calculation result to the partial-sum accumulation block 230. The partial-sum accumulation block 230 may add all the first to fourteenth initial calculation results to coincide with the digits and may generate the overall calculation result. In an embodiment, the partial-sum accumulation block 230 may add initial calculation results for each digit simultaneously while receiving the first to fourteenth initial calculation results and may generate the overall calculation result.

FIG. 13B shows another example in which the memory block 600 performs a calculation operation. For convenience, in FIG. 13B, the description will be given based on the condition that respective activation values are stored in the second memory cell array 612 connected to 32nd to 63rd wordlines WL32 to WL63 and 32nd to 63rd wordline bars WLB32 to WLB63. For example, the A12-th activation value A12 may be stored in memory cells connected to the 32nd to 39th wordlines WL32 to WL39 and the 32nd to 39th wordline bars WLB32 to WLB39; in the above manner, the B12-th activation value B12, the C12-th activation value C12, and the D12-th activation value D12 may be in a state of being sequentially stored in the second memory cell array 612.

In FIG. 13B, a magnitude of a weight to be applied to the A12-th activation value A12 may be “4” being the 2 power of 2, and a magnitude of a weight to be applied to the B12-th activation value B12 may be “1” being the 0 power of 2. A magnitude of a weight to be applied to the C12-th activation value C12 may be “32” being the 5 power of 2, and a magnitude of a weight to be applied to the D12-th activation value D12 may be “2” being the 1 power of 2.

The memory block 600 may compute bits of the first digit. Because only one bit is present at the first digit, the bit of the first digit and a bit of the second digit may be computed. The wordline decoder 620 may apply the turn-on voltage to the 46th wordline WL46 and the 47th wordline bar WLB47 of the second memory cell array 612 such that the sixth bit B12[6] of the B12-th activation value B12 and the seventh bit B12[7] of the B12-th activation value B12 are read. The sixth bit B12[6] of the B12-th activation value B12 and the seventh bit B12[7] of the B12-th activation value B12 may be transferred to the second shift adder 662 (e.g., simultaneously or almost simultaneously). In this case, because bits of different digits are read, the shift adder controller 650 may set the shift signal SH to logic “1”. The second shift adder 662 may generate a first initial calculation result by adding the sixth bit B12[6] of the B12-th activation value B12 and the seventh bit B12[7] of the B12-th activation value B12. The second shift adder 662 may transfer the first initial calculation result to the adder tree 670, and the adder tree 670 may transfer the first initial calculation result to the partial-sum accumulation block 230.

Like the method of generating the first initial calculation result, the memory block 600 may generate a second initial calculation result by summing the seventh bit D12[7] of the D12-th activation value D12 and the seventh bit A12[7] of the A12-th activation value A12. Next, the memory block 600 may add the remaining bits of the third digit. The wordline decoder 620 may apply the turn-on voltage to the 45th wordline WL45 and the 62nd wordline bar WLB62 such that the fifth bit B12[5] of the B12-th activation value B12 and the sixth bit D12[6] of the D12-th activation value D12 are read. The fifth bit B12[5] of the B12-th activation value B12 and the sixth bit D12[6] of the D12-th activation value D12 may be transferred to the second shift adder 662 (e.g., simultaneously or almost simultaneously). As bits of the same digit are read, the shift adder controller 650 may set the shift signal SH to logic “0”. The second shift adder 662 may generate a third initial calculation result by summing the fifth bit B12[5] of the B12-th activation value B12 and the sixth bit D12[6] of the D12-th activation value D12. The second shift adder 662 may transfer the third initial calculation result to the adder tree 670, and the adder tree 670 may transfer the third initial calculation result to the partial-sum accumulation block 230.

As in the above method of generating the third initial calculation result, the memory block 600 may generate a fourth initial calculation result by summing the sixth bit A12[6] of the A12-th activation value A12 and the fourth bit B12[4] of the B12-th activation value B12 and may transfer the fourth initial calculation result to the partial-sum accumulation block 230. As in the above method of generating the first initial calculation result, the memory block 600 may generate a fifth initial calculation result by summing the fifth bit A12[5] of the A12-th activation value A12 and the fifth bit D12[5] of the D12-th activation value D12 and may transfer the fifth initial calculation result to the partial-sum accumulation block 230. As in the above method of generating the first initial calculation result or the second initial calculation result, the memory block 600 may generate sixth to fourteenth initial calculation results and may transfer the sixth to fourteenth initial calculation results to the partial-sum accumulation block 230. The partial-sum accumulation block 230 may add all the first to fourteenth initial calculation results to coincide with the digits and may generate the overall calculation result. In an embodiment, the partial-sum accumulation block 230 may add initial calculation results for each digit simultaneously while receiving the first to fourteenth initial calculation results and may generate the overall calculation result.

In an embodiment, the memory block 600 may perform the weight calculation of activation values included in the first memory cell array 611 of FIG. 13A and the weight calculation of activation values included in the second memory cell array 612 of FIG. 13A at the same time and may sum two weight calculation results. In an embodiment, the weight management block 210 of FIG. 3 may control the wordline decoder 620 such that the weight calculation of the first memory cell array 611 and the weight calculation of the second memory cell array 612 are simultaneously performed. In an embodiment, the weight management block 210 may control the wordline decoder 620 such that the digit of the initial calculation result provided from the first shift adder 661 to the adder tree 670 is the same as the digit of the initial calculation result provided from the second shift adder 662 to the adder tree 670. Under control of the weight management block 210, the wordline decoder 620 may determine wordlines and wordline bars to which the turn-on voltage is to be applied such that the digits of the initial calculation results provided to the adder tree 670 are matched. In an embodiment, the adder tree 670 may generate intermediate calculation results by summing initial calculation results received from the first shift adder 661 and initial calculation results received from the second shift adder 662 and may transfer the intermediate calculation results to the partial-sum accumulation block 230. In an embodiment, the partial-sum accumulation block 230 may generate the overall calculation result by summing the intermediate calculation results for each digit.

For example, referring to FIGS. 13A and 13B together, the memory block 600 may compute bits of the first digit. The wordline decoder 620 may apply the turn-on voltage to the sixth wordline WL6 and the seventh wordline bar WLB7 such that bits to be computed are provided to the first shift adder 661 and may apply the turn-on voltage to the 46th wordline WL46 and the 47th wordline bar WLB47 such that bits to be computed are provided to the second shift adder 662. The first shift adder 661 and the second shift adder 662 may generate initial calculation results and may transfer the initial calculation results to the adder tree 670, and the adder tree 670 may sum the initial calculation results to generate a first intermediate calculation result.

Next, the memory block 600 may compute bits of the second digit. In this case, when a weight is applied to activation values stored in the first memory cell array 611, because there are not bits corresponding to the digit, the memory block 600 may perform the calculation operation only on the second memory cell array 612. The wordline decoder 620 may apply the turn-on voltage to the 39th wordline WL39 and the 63rd wordline bar WLB63 such that bits to be computed are provided to the second shift adder 662. The second shift adder 662 may provide the initial calculation result to the adder tree 670. Because there is no corresponding initial calculation result of the first shift adder 661, the adder tree 670 may transfer the initial calculation result to the partial-sum accumulation block 230 as a second intermediate calculation result.

The memory block 600 may compute bits of the third digit. Under control of the weight management block 210, the wordline decoder 620 may apply the turn-on voltage to the fifth wordline WL5, the 15th wordline bar WLB15, the 38th wordline WL38, and the 62nd wordline bar WLB62. The first shift adder 661 may generate an initial calculation result by adding bits read when the turn-on voltage is applied the fifth wordline WL5 and the 15th wordline bar WLB15 and may transfer the initial calculation result to the adder tree 670. The second shift adder 662 may generate an initial calculation result by adding bits read when the turn-on voltage is applied the 38th wordline WL38 and the 62nd wordline bar WLB62 and may transfer the initial calculation result to the adder tree 670. In this case, because digits of bits input to the second shift adder 662 are different, the shift signal SH may be logic “1”. The adder tree 670 may generate a third intermediate calculation result by adding the initial calculation result of the first shift adder 661 and the initial calculation result of the second shift adder 662 and may transfer the third intermediate calculation result to the partial-sum accumulation block 230.

As in the above methods, the memory block 600 may perform the calculation operation even on different bits of different digits. The adder tree 670 may transfer intermediate calculation results including the first to third intermediate calculation results to the partial-sum accumulation block 230. The partial-sum accumulation block 230 may add all the received intermediate calculation results to coincide with the digits and may generate the overall calculation result.

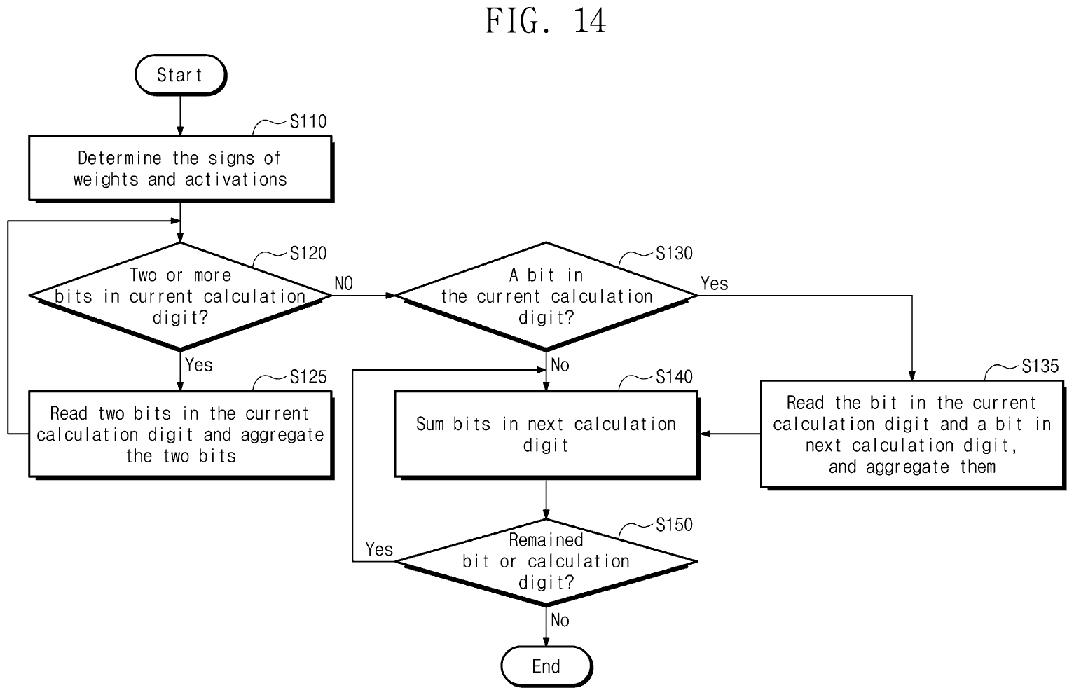

FIG. 14 is a flowchart illustrating an operation method of the memory cluster module 200, according to an embodiment of the present disclosure. An operation method of the memory block 600 according to an embodiment of the present disclosure will be described with reference to FIGS. 3 to 14.

In operation S110, the memory cluster module 200 may determine signs of weights and activation values. In an embodiment, the weight management block 210 may determine the sign of each weight, based on the MSB of each weight. In an embodiment, the weight management block 210 may determine the sign of each activation values, based on the MSB of each activation value stored in the memory block 600.

In an embodiment, the weight management block 210 may determine the sign of each of the activation values to which the weights are respectively applied, based on determining the signs of the weights and the activation values. In the memory cluster module 200, the determined signs may be applied to the shift adder controller 650 of the memory block 600. In an embodiment, under control of the weight management block 210, the shift adder controller 650 may control the shift adders 661 and 662 such that a determined sign of a value whose weight is applied to an activation value is applied to the calculation operation.

In operation S120, the memory cluster module 200 may determine a next step depending on whether two or more bits remain in the current calculation digit. The calculation digit which is conceptual may include digits aligned as illustrated in FIGS. 13A and 13B. That is, the calculation digit described with reference to FIG. 14 may be implemented depending on how the weight management block 210 of FIG. 3 controls the wordline decoder 620 and may be implemented based on determining bits of activation values which the wordline decoder 620 reads. When two or more bits to be computed are present in the current calculation digit, the memory cluster module 200 may perform operation S125; when the number of bits to be computed in the current calculation digit is less than 2, the memory cluster module 200 may perform operation S130.

In operation S125, the memory cluster module 200 may read two bits in the current digit and may sum the two bits. In an embodiment, the memory block 600 may read and add two bits in the current calculation digit, which are stored in a memory cell array (e.g., the first memory cell array 611). For example, based on the operation described with reference to FIGS. 8 to 13B, the memory block 600 may read two bits and may add the two bits.

In an embodiment, the memory block 600 may transfer an initial calculation result generated by adding two bits to the adder tree 670, and the adder tree 670 may transfer the initial calculation result to the partial-sum accumulation block 230. In an embodiment, the adder tree 670 may generate an intermediate calculation result by summing initial calculation results received from any other shift adders and the intermediate calculation result may be transferred to the partial-sum accumulation block 230. After operation S125, the memory cluster module 200 may return to operation S120.

In operation S130, the memory cluster module 200 may determine a next step depending on whether the number of bits to be computed in the current calculation digit is one. When the number of bits to be computed in the current calculation digit is one, the memory cluster module 200 may proceed to operation S135. When there is no bit to be computed in the current calculation digit, the memory cluster module 200 may proceed to operation S140.

In operation S135, the memory cluster module 200 may compute the remaining bit in the current calculation digit and one bit in a next calculation digit. For example, through a method similar to the method of generating the first initial calculation result of FIG. 13A, the memory block 600 may compute the remaining bit in the current calculation digit and one bit in a next calculation digit. In an embodiment, when there is no bit to be computed in the next calculation digit, the memory block 600 may generate a calculation result only using one bit in the current calculation digit. The memory block 600 may transfer the generated calculation result to the partial-sum accumulation block 230. The partial-sum accumulation block 230 may sum the received calculation result and previously accumulated calculation results so as to coincide with the digit. After operation S135, the memory cluster module 200 may return to operation S140.

In operation S140, the memory cluster module 200 may perform the calculation operation on the next calculation digit. In an embodiment, the memory cluster module 200 may sum bits included in the next calculation digit, based on operation S120 to operation S135. The partial-sum accumulation block 230 may receive and accumulate a calculation result of bits in the next calculation digit. In an embodiment, the partial-sum accumulation block 230 may add the received calculation result and a previously received calculation result to coincide with the digit. After operation S140, the memory cluster module 200 may return to operation S150.

In operation S150, the memory cluster module 200 may determine whether there is a next calculation digit. When there is a next calculation digit, the memory cluster module 200 may return to operation S140 and may perform compute bits of the next calculation digit. When there is no next calculation digit, the memory cluster module 200 may terminate the calculation operation. In an embodiment, the partial-sum accumulation block 230 may generate the overall calculation result by adding all the calculation results received based on the iteration of operation S120 to operation S130 and operation S140 so as to coincide with the digit.

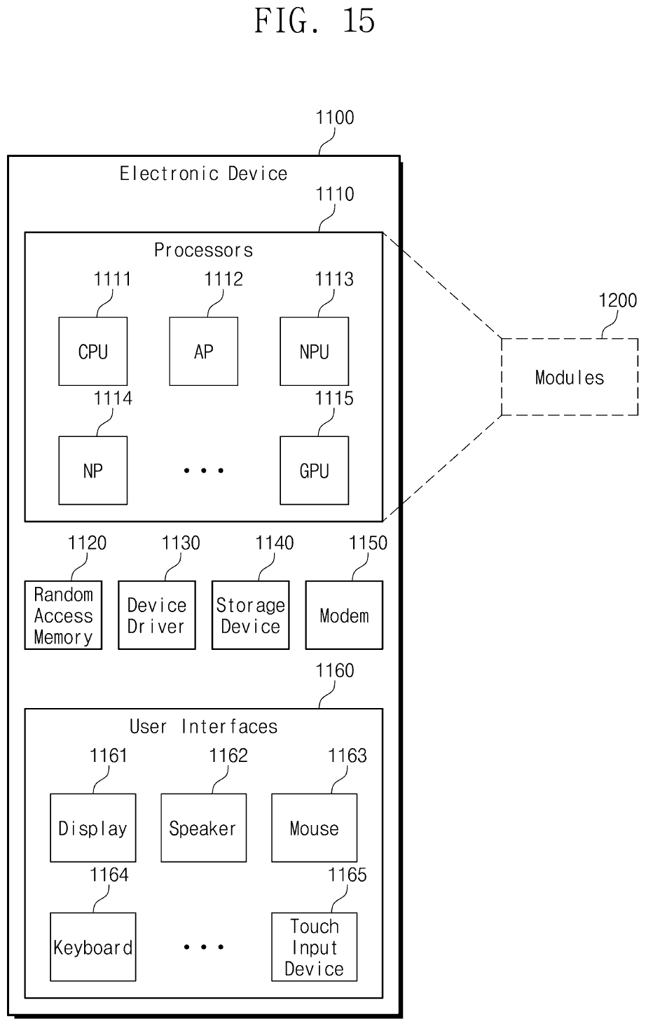

FIG. 15 is a block diagram illustrating an electronic device according to an embodiment of the present disclosure. Referring to FIG. 15, an electronic device 1100 may include processors 1110, a random access memory 1120, a device driver 1130, a storage device 1140, a modem 1150, and user interfaces 1160.

The processors 1110 may include, for example, a central processing unit (CPU) 1111 or at least one general-purpose processor such as an application processor (AP) 1112. The processor 1110 may include at least one special-purpose processor such as a neural processing unit 1113, a neuromorphic processor 1114, or a graphics processing unit 1115. The processor 1110 may include two or more homogeneous processors.

In an embodiment, the special-purpose processor may be an accelerator described with reference to FIGS. 1 to 14 or may include the accelerator. For example, the neural processing unit 1113, the neuromorphic processor 1114, or the graphics processing unit 1115 may include the accelerators described with reference to FIGS. 1 to 14.

At least one of the processors 1110 may execute modules 1200. For example, at least some of the modules 1200 may include a module trained based on the machine learning or deep learning, and at least others of the modules 1200 may include a module operating based on a given algorithm.

At least one of the processors 1110 may be used to train the modules 1200 (e.g., some associated with the learning from among the modules 200) or may be used to execute the trained modules 1200. At least one of the processors 1110 may train or execute the modules 1200 based on a variety of data or information. For example, the modules 1200 may be implemented in the form of instructions (or codes) that are executed by at least one of the processors 1110. In this case, the at least one processor may load the instructions (or codes) of the modules 1200 to the random access memory 1120.

As another example, the at least one among the processors 1110 (or at least another of the processors 1110) may be manufactured to implement the modules 1200. For example, the at least one processor may be a dedicated processor that is implemented in hardware based on the modules 1200 generated by the learning of the modules 1200.

As another example, the at least one among the processors 1110 (or at least another of the processors 1110) may be manufactured to implement various machine learning or deep learning modules. The at least one processor may implement the modules 1200 by receiving information (e.g., instructions or codes) corresponding to the modules 1200.

The random access memory 1120 may be used as a working memory of the processors 1110 and may be used as a main memory or a system memory of the electronic device 1000. The random access memory 1120 may include a volatile memory such as a dynamic random access memory or a static random access memory, or a nonvolatile memory such as a phase-change random access memory, a ferroelectric random access memory, a magnetic random access memory, or a resistive random access memory.

The device driver 1130 may control the following peripheral devices depending on a request of the processors 1110: the storage device 1140, the modem 1150, and the user interfaces 1160. The storage device 1140 may include a stationary storage device such as a hard disk drive or a solid state drive, or a removable storage device such as an external hard disk drive, an external solid state drive, or a removable memory card.

The modem 1150 may provide remote communication with the external device. The modem 1150 may perform wired or wireless communication with the external device. The modem 1150 may communicate with the external device based on at least one of various communication schemes such as Ethernet, wireless-fidelity (Wi-Fi), long term evolution (LTE), and 5th generation (5G) mobile communication.

The user interfaces 1160 may receive information from the user and may provide information to the user. The user interfaces 1160 may include at least one user output interface such as a display 1161 or a speaker 1162, and at least one user input interface such as a mouse 1163, a keyboard 1164, or a touch input device 1165.

The instructions (or codes) of the modules 1200 may be received through the modem 1150 and may be stored in the storage device 1140. The instructions (or codes) of the modules 1200 may be stored in a removable storage device, and the removable storage device may be connected to the electronic device 1000. The instructions (or codes) of the modules 1200 may be loaded to the random access memory 1120 from the storage device 1140 so as to be executed.

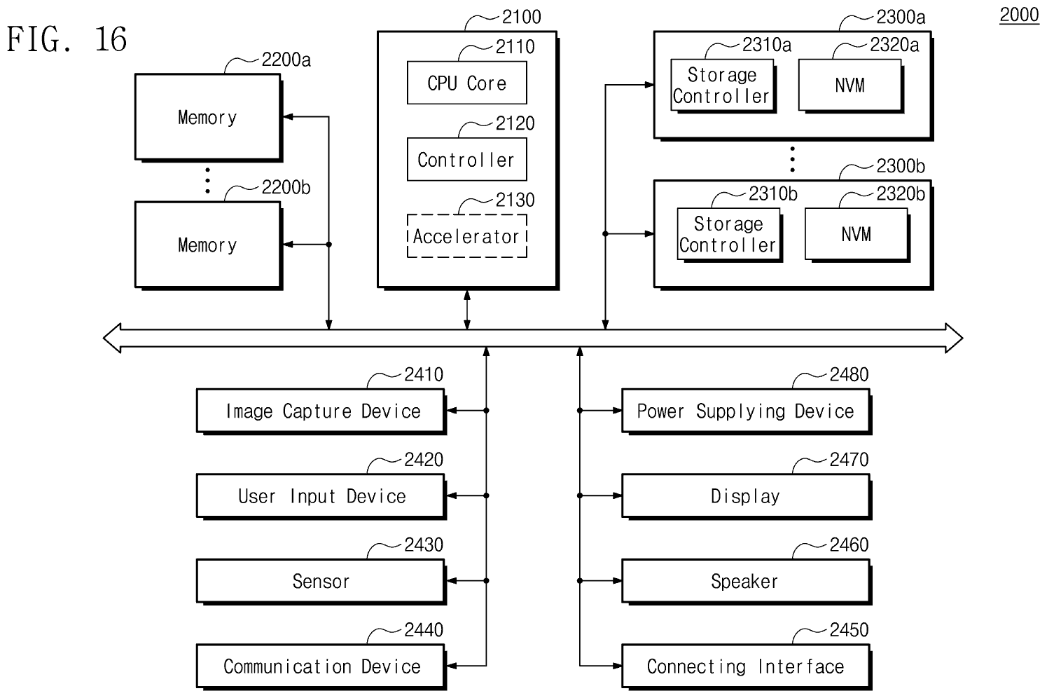

FIG. 16 is a diagram of a system 2000 to which a storage device is applied, according to an embodiment. The system 2000 of FIG. 16 may basically be a mobile system, such as a portable communication terminal (e.g., a mobile phone), a smartphone, a tablet personal computer (PC), a wearable device, a healthcare device, or an Internet of things (IOT) device. However, the system 2000 of FIG. 16 is not necessarily limited to the mobile system and may be a PC, a laptop computer, a server, a media player, or an automotive device (e.g., a navigation device).

Referring to FIG. 16, the system 2000 may include a main processor 2100, memories (e.g., 2200a and 2200b), and storage devices (e.g., 2300a and 2300b). In addition, the system 2000 may include at least one of an image capturing device 2410, a user input device 2420, a sensor 2430, a communication device 2440, a connecting interface 2450, a speaker 2460, a display 2470, and a power supplying device 2480.

The main processor 2100 may control all operations of the system 2000, more specifically, operations of other components included in the system 2000. The main processor 2100 may be implemented as a general-purpose processor, a dedicated processor, or an application processor.

The main processor 2100 may include at least one CPU core 2110 and further include a controller 2220 configured to control the memories 2200a and 2200b and/or the storage devices 2300a and 2300b. In some embodiments, the main processor 2100 may further include an accelerator 2230, which is a dedicated circuit for a high-speed data operation, such as an artificial intelligence (AI) data operation. The accelerator 2230 may include a graphics processing unit (GPU), a neural processing unit (NPU) and/or a data processing unit (DPU) and be implemented as a chip that is physically separate from the other components of the main processor 2100. The accelerator 2130 may be or include the accelerator described in FIGS. 1 to 14.

The memories 2200a and 2200b may be used as main memory devices of the system 2000. Although each of the memories 2200a and 2200b may include a volatile memory, such as static random access memory (SRAM) and/or dynamic RAM (DRAM), each of the memories 2200a and 2200b may include non-volatile memory, such as a flash memory, phase-change RAM (PRAM) and/or resistive RAM (RRAM). The memories 2200a and 2200b may be implemented in the same package as the main processor 2100.

The storage devices 2300a and 2300b may serve as non-volatile storage devices configured to store data regardless of whether power is supplied thereto, and have larger storage capacity than the memories 2200a and 2200b. The storage devices 2300a and 2300b may respectively include storage controllers (STRG CTRL) 2310a and 2310b and NVM (Non-Volatile Memory)s 2320a and 2320b configured to store data via the control of the storage controllers 2310a and 2310b. Although the NVMs 2320a and 2320b may include flash memories having a two-dimensional (2D) structure or a three-dimensional (3D) V-NAND structure, the NVMs 2320a and 2320b may include other types of NVMs, such as PRAM and/or RRAM.

The storage devices 2300a and 2300b may be physically separated from the main processor 2100 and included in the system 2000 or implemented in the same package as the main processor 2100. In addition, the storage devices 2300a and 2300b may have types of solid-state devices (SSDs) or memory cards and be removably combined with other components of the system 100 through an interface, such as the connecting interface 2450 that will be described below. The storage devices 2300a and 2300b may be devices to which a standard protocol, such as a universal flash storage (UFS), an embedded multi-media card (eMMC), or a non-volatile memory express (NVMe), is applied, without being limited thereto.

The image capturing device 2410 may capture still images or moving images. The image capturing device 2410 may include a camera, a camcorder, and/or a webcam.

The user input device 2420 may receive various types of data input by a user of the system 2000 and include a touch pad, a keypad, a keyboard, a mouse, and/or a microphone.

The sensor 2430 may detect various types of physical quantities, which may be obtained from the outside of the system 2000, and convert the detected physical quantities into electric signals. The sensor 2430 may include a temperature sensor, a pressure sensor, an illuminance sensor, a position sensor, an acceleration sensor, a biosensor, and/or a gyroscope sensor.

The communication device 2440 may transmit and receive signals between other devices outside the system 2000 according to various communication protocols. The communication device 2440 may include an antenna, a transceiver, and/or a modem.

The connecting interface 2450 may provide connection between the system 2000 and an external device, which is connected to the system 2000 and capable of transmitting and receiving data to and from the system 2000. The connecting interface 2450 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 2394, a universal serial bus (USB) interface, a secure digital (SD) card interface, a multi-media card (MMC) interface, an eMMC interface, a UFS interface, an embedded UFS (eUFS) interface, and a compact flash (CF) card interface.

The speaker 2460 and the display 2470 may serve as output devices configured to respectively output auditory information and visual information to the user of the system 2000.

The power supplying device 2480 may appropriately convert power supplied from a battery (not shown) embedded in the system 2000 and/or an external power source, and supply the converted power to each of components of the system 2000.

According to an embodiment of the present disclosure, a memory device providing a compute-in-memory capable of enabling the fast execution of multiplication and addition between an activation value and a weight within the memory device and reducing power consumption, an operation method of the memory device, and an electronic device including the memory device are provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A memory device comprising:
a wordline decoder configured to control a plurality of wordlines and to select a wordline, to which a first turn-on voltage is applied, depending on a weight value to be applied to an activation value;
a first memory cell array including memory cells respectively connected to wordlines including a first wordline and a second wordline from among the plurality of wordlines; and
a shift adder connected to the first memory cell array through a first bitline and a first bitline bar and configured to generate a first initial calculation result by adding a first input received through the first bitline and a second input received through the first bitline bar,
wherein the first memory cell array stores a first activation value including a first bit and a second bit,
wherein the first bit is stored in a first memory cell connected to the first wordline, and
wherein the second bit is stored in a second memory cell connected to the second wordline.

2. The memory device of claim 1, wherein the first memory cell array further includes memory cells respectively connected to a third wordline and a fourth wordline from among the plurality of wordlines and further stores a second activation value including a third bit and a fourth bit,
wherein the third bit is stored in a third memory cell connected to the third wordline, and
wherein the fourth bit is stored in a fourth memory cell connected to the fourth wordline.

3. The memory device of claim 1, wherein the wordline decoder is further configured to:
control a plurality of wordline bars; and
select a wordline bar to which a second turn-on voltage is applied, depending on a weight value, and
wherein the plurality of wordline bars include wordline bars respectively connected to the plurality of memory cells included in the first memory cell array.

4. The memory device of claim 3, further comprising:
a shift adder controller configured to provide the shift adder with sign information of the first input and sign information of the second input.

5. The memory device of claim 3, wherein the wordline decoder is configured to:
apply the first turn-on voltage to one wordline among the plurality of wordlines such that data of a memory cell connected to the wordline to which the first turn-on voltage is applied are transferred to the shift adder through the first bitline; and
apply the second turn-on voltage to one wordline bar among the plurality of wordline bars such that data of a memory cell connected to the wordline bar to which the second turn-on voltage is applied are transferred to the shift adder through the first bitline bar.

6. The memory device of claim 4, wherein the shift adder includes:
a first multiplexer including a first input terminal connected to the first bitline and a second input terminal receiving logic “0”, and configured to select a first output value in response to the sign information of the first input;
a NOT gate including an input connected to the first bitline bar;
a second multiplexer including a first input terminal connected to an output terminal of the NOT gate and a second input terminal receiving logic “0”, and configured to select a second output value in response to the sign information of the second input;
a third multiplexer including a first input terminal connected to the first bitline and a second input terminal receiving logic “0”, and configured to select a third output value in response to an inverse signal of shift signal; and
a fourth multiplexer including a first input terminal connected to the first bitline and a second input terminal receiving the first output value of the first multiplexer, and configured to select a fourth output value in response to the shift signal, and
wherein the shift adder generates the first initial calculation result, based on the first output value, the second output value, the third output value, and the fourth output value.

7. The memory device of claim 6, wherein the calculation result is implemented with three bits including a most significant bit, an intermediate bit, and a least significant bit,
wherein the shift adder further includes:
a half adder configured to add an output value of the NOT gate and the third output value and to output a first carry and the least significant bit of the calculation result;
a first full adder configured to add the first carry, the second output value, and the fourth output value and to output a second carry and the intermediate bit of the calculation result; and
a second full adder configured to add the second carry, the first output value, and the second output value and to output the most significant bit of the calculation result.

8. The memory device of claim 4, wherein the shift adder includes a first shift adder, and
wherein the memory device further comprises:
a second memory cell array including memory cells respectively connected to a fifth wordline and a sixth wordline among the plurality of wordlines;
a second shift adder connected to the second memory cell array through the first bitline and the first bitline bar and to generate a second initial calculation result by adding a third input received through the first bitline and a fourth input received through the first bitline bar; and
an adder tree connected to the first shift adder and the second shift adder, and configured to add the first initial calculation result and the second initial calculation result.

9. The memory device of claim 8, wherein the second memory cell array stores a third activation value including a fifth bit and a sixth bit,
wherein the fifth bit is stored in a fifth memory cell connected to the fifth wordline, and
wherein the sixth bit is stored in a sixth memory cell connected to the sixth wordline.

10. The memory device of claim 9, wherein the plurality of memory cells are static random access memory (SRAM) cells.

11. The memory device of claim 9, wherein the first memory cell includes:
an n-type metal-oxide-semiconductor (NMOS) transistor connected between the first bitline and a first node and including a gate node connected to the first wordline;
a PMOS transistor connected between the first bitline bar and a second node and including a gate node connected to a first wordline bar;
a first inverter including an input terminal connected to the first node and an output terminal connected to the second node; and
a second inverter including an input terminal connected to the second node and an output terminal connected to the first node.

12. The memory device of claim 9, wherein the first activation value and the third activation value are stored in a sign-magnitude form, and
wherein the first initial calculation result and the second initial calculation result express a negative number in the form of a 2's complement.

13. An operation method of a memory device which provides a compute-in-memory, the method comprising:
determining signs of a first activation value and a second activation value stored in a memory cell array including a plurality of memory cells connected to a plurality of wordlines;
determining a sign of a first weight to be applied to the first activation value and a sign of a second weight to be applied to the second activation value; and
adding a first calculation result obtained by applying the first weight to the first activation value and a second calculation result obtained by applying the second weight to the second activation value for each digit,
wherein the first activation value is stored in first memory cells respectively connected to wordlines including a first wordline and a second wordline from among the plurality of wordlines, and
wherein the first weight is applied to the first activation value, based on selecting a wordline, to which a first turn-on voltage is applied, from among the plurality of wordlines.

14. The method of claim 13, wherein the first activation value includes:
a first bit stored in a first memory cell connected to the first wordline; and
a second bit stored in a second memory cell connected to the second wordline, and
wherein the first memory cells are respectively connected to first wordline bars.

15. The method of claim 13, wherein the second activation value is stored in second memory cells respectively connected to wordlines including a third wordline and a fourth wordline from among the plurality of wordlines, and
wherein the second activation value includes:
a third bit stored in a third memory cell connected to the third wordline; and
a fourth bit stored in a fourth memory cell connected to the fourth wordline.

16. The method of claim 14, wherein the first weight is applied to the first activation value, further based on selecting a wordline bar, to which a second turn-on voltage is applied, from among the first wordline bars.

17. The method of claim 16, wherein a fifth bit corresponding to a first digit of the first calculation result is transferred to a shift adder, based on that a first turn-on voltage is applied to a wordline connected to a fifth memory cell storing the fifth bit,
wherein a sixth bit corresponding to the first digit of the second calculation result is transferred to the shift adder, based on that a second turn-on voltage is applied to a wordline bar connected to a memory cell storing the sixth bit, and
wherein the shift adder generates a first initial calculation result by adding the fifth bit and the sixth bit.

18. An accelerator comprising:
a processing unit configured to control the accelerator and to perform an operation of the accelerator; and
a memory cluster module configured to store data of the accelerator and to provide a compute-in-memory,
wherein the memory cluster module includes:
a memory block configured to store the data including activation values and to perform a weight calculation between the activation values;
a weight management block configured to control the memory block such that weights are applied to the activation values; and
a partial-sum accumulation block configured to sum an initial calculation result generated by the memory block to generate an overall calculation result,
wherein the memory block includes:
a wordline decoder configured to control a plurality of wordlines including a first wordline and a second wordline and to apply the weights to the activation values, based on selecting a wordline to which a first turn-on voltage is applied; and
a memory cell array connected to the plurality of wordlines and configured to store a first activation value including a first bit and a second bit, and
wherein the first bit is stored in a first memory cell connected to a first wordline, and the second bit is stored in a second memory cell connected to the second wordline.

19. The accelerator of claim 18, wherein the memory block further includes:
a shift adder connected to a first bitline and a first bitline bar connected to the memory cell array, and configured to sum a third bit received through the first bitline and a fourth bit received through the first bitline bar.

20. The accelerator of claim 19, wherein the memory cell array is further connected to a plurality of wordline bars,
wherein the third bit is read from a memory cell connected to a wordline, to which the first turn-on voltage is applied, from among the plurality of wordlines, and
wherein the fourth bit is connected to a memory cell connected to a wordline bar, to which a second turn-on voltage is applied, from among the plurality of wordline bars.
